(19) United States
(12) Patent Application Publication
(10) Pub. No.: US 2015/0378415 A1
(43) Pub. Date: Dec. 31, 2015

(54) BACK-UP POWER SUPPLY SYSTEMS AND METHODS FOR USE WITH SOLID STATE STORAGE DEVICES

(71) Applicant: Christopher George, Palo Alto, CA (US)

(72) Inventor: Christopher George, Palo Alto, CA (US)

(21) Appl. No.: 14/615,308

(22) Filed: Feb. 5, 2015

Related U.S. Application Data
(60) Provisional application No. 61/936,260, filed on Feb. 5, 2014.

(51) Int. Cl. G06F 1/30; H02J 7/00; H02J 9/06; G11C 5/14; G11C 14/00

(52) U.S. Cl. CPC G06F 1/30; G11C 5/141; G11C 14/0018; H02J 9/061; H02J 7/0052; H02J 7/0042; H02J 7/345

(57) ABSTRACT

Back-up power systems and methods for use with solid-state storage systems. A back-up power device includes an energy storage unit and first and second connections. A charge source is attachable to the first connection, the charge source providing a charge current to the first connection, with the charge current circumventing or bypassing a data storage device, wherein the first connection provides the charge current to the charging circuit, and the charging circuit charges the energy storage unit. The data storage device is attachable to the second connection, the energy storage unit providing a back-up power to the second connection, with the second connection providing the back-up power to the data storage device. The power pack is particularly useful for providing back up power to a data storage module or device that includes volatile and non-volatile memory units, such as a PCIe based data storage module.

### CROSS-REFERENCE TO RELATED APPLICATIONS

This patent application claims the benefit of U.S. Provisional Patent Application No. 61/936,260, filed Feb. 5, 2014, which is hereby incorporated by reference in its entirety.

### BACKGROUND

The present disclosure relates generally to the field of data storage, and in particular to methods and apparatus for providing back-up power to solid state storage devices.

Data storage systems and modules are widely used. Examples include solid state storage systems, such as PCIe (Peripheral Component Interconnect Express) data storage accelerator systems, that include non-volatile and volatile memory. It is desirable that such data storage devices maintain data integrity in the event of a loss of host (main) power. In such case, a sufficient amount of back-up power is needed to transfer data stored in volatile memory to non-volatile memory to guarantee data integrity.

It is therefore desirable to provide back-up power solutions to guarantee data integrity of such data storage systems.

### SUMMARY

Embodiments of the present disclosure provide systems and methods that provide back-up power for data storage systems, in particular solid state storage devices, and other systems.

According to an embodiment, a back-up power pack device is provided. The power pack device typically includes an energy storage unit, a first connection, a second connection and a charging circuit. A charge source is attachable to the first connection, the charge source providing a charge current to the first connection, the charge current circumventing or bypassing a data storage device, wherein the first connection provides the charge current to the charging circuit, and the charging circuit charges the energy storage unit, and wherein the data storage device is attachable to the second connection, the energy storage unit providing a back-up power to the second connection, the second connection providing the back-up power to the data storage device. The power pack is particularly useful for providing back up power to a data storage module that includes volatile and non-volatile memory units, such as a PCIe based data storage module.

In certain aspects, the first connection comprises a first power connector, and the charge source couples to the first power connector via a power cable. In certain aspects, the charge source includes one of a power supply unit connection, a motherboard connection, a motherboard riser connection, or a PCIe charge supply card connection.

In certain aspects, the back-up power pack includes a load switch that controls coupling of energy from the power storage unit to the second connection. The energy storage unit provides the back-up power to the load switch, the back-up power is coupled to the second connection when the load switch is in a first switch state and the back-up power is uncoupled from the second connection when the load switch is in a second switch state. In certain aspects, the back-up power pack includes a memory element, wherein the memory element transitions to a first element state when an energy storage voltage reaches a first predefined voltage and the memory element transitions to a second element state when the energy storage voltage reaches a second predefined voltage, wherein the load switch transitions to the first switch state when the memory element transitions to the first element state and the load switch transitions to the second switch state when the memory element transitions to the second element state.

In certain aspects, the power pack further includes a temperature logging system, wherein a temperature is sampled at a sample rate and a temperature value is stored to a non-volatile sample memory at a store rate, wherein the temperature value is a highest temperature value in a set of temperature values sampled since a last temperature value was stored. In certain aspects, the non-volatile sample memory has a capacity to store a back-up power pack warranty period worth of samples at the sample rate and a retention period of the non-volatile sample memory (after all samples have been stored) exceeds the warranty period. In certain aspects, wherein the sample rate is once per second, the store rate is once per minute and the warranty period is five years.

In certain aspects, the data storage device or system connects to a host, e.g., via a motherboard, using one of a PCIe slot or a DIMM connector.

According to another embodiment, a back-up power device for use in providing power to an external data storage device is provided. The back-up power device typically includes an energy storage unit, a first terminal or connector that provides, or is configurable to provide, back-up power from the energy storage unit to a data storage device connected to the first terminal or connector, and a second terminal or connector that receives charging current from a charging source that is external to the power pack and separate and distinct from the data storage device. The back-up power device also typically includes a charging circuit coupled with the energy storage unit and the second terminal or connector, wherein the charging circuit sources charging current from the charging source and charges the energy storage unit, whereby the charging current circumvents the attached storage device or is derived from a source other than the storage device.

In certain aspects, the power source comprises a power supply unit connected to the second terminal or connector via a cable. In certain aspects, the charging source comprises a power connector of a motherboard in a host system. In certain aspects, the motherboard includes a riser and wherein the riser includes the power. In certain aspects, the charging source includes a charge supply card connected to one of a motherboard or a motherboard riser in a host system. In certain aspects, the energy storage unit includes one or a plurality of supercapacitors. In certain aspects, the charging circuit charges the energy storage unit at a rate of about 3 Amperes (from a 12V source).

According to another embodiment, a method of providing back-up power to a data storage device from a back-up power device is provided. The back-up power device typically includes a first power connection, a second power connection and an energy storage unit, wherein the data storage device is coupled with the first power connection. The method typically includes sourcing charge current from a charge source to the energy storage unit of the back-up power device, wherein the charge source is coupled to the second connection and the charge current circumvents or bypasses the data storage device. The method also typically includes, responsive to a trigger signal received from the data storage device, providing back-up charge current from the power storage unit to the first power connection. In certain aspects, sourcing charge current from a charge source includes sourcing current from the charge source using a charging circuit coupled between the second power connector and the power storage unit, and charging the power storage unit using the charging circuit. In certain aspects, the charge source includes one of a power supply unit of a host system, a connector of a motherboard in the host system, a connector of a motherboard riser in the host system or a charge supply card connected to one of the motherboard or the mother board riser. In certain aspects, the energy storage unit includes one or a plurality of supercapacitors. In certain aspects, the data storage device is comprised of one of a PCIe card or a DIMM module. In certain aspects, the data storage device includes volatile memory and non-volatile memory.

According to yet another embodiment a back-up power pack is provided that typically includes an energy storage unit, a first connector operable to receive a charge current provided by a charge source, wherein the charge source is attached to the first connector and the charge current circumvents a data storage device, wherein the data storage device is attached to a second connector, wherein the second connector is operable to provide back-up power sourced from the energy storage unit to the data storage device, and a charging circuit includes an input and an output, wherein the input is coupled to the first connector and the output is coupled to the energy storage unit.

According to an embodiment, a back-up power pack device for use with a solid-state storage device is provided. The back-up power pack typically includes a first printed circuit board (PCB) including power control electronics and a first electrical interface, a second PCB including a second electrical interface configured to removably mate with the first electrical interface of the first PCB, and one or a plurality of supercapacitors connected to the second PCB such that a length of the supercapacitor(s) extends substantially perpendicular to a plane defined by the second PCB. When the second electrical interface of the second PCB is mated with first electrical interface of the first PCB, the length of the plurality of supercapacitors extends substantially parallel to a plane defined by the first PCB, and whereby the plurality of supercapacitors provide power to the power control electronics through the mated first and second electrical connectors.

In certain aspects, the back-up power pack further includes a housing structure that holds the first PCB and which is configured to receive and enclose the supercapacitors when the first electrical interface is mated with the second electrical interface. In certain aspects, the housing structure comprises a unitary folded sheet of aluminum. In certain aspects, the first and second electrical connectors comprise a 14 pin header/receiver pair. In certain aspects, the housing structure includes a plurality of openings positioned proximal to where an end of each of the supercapacitors would be when the second electrical interface of the second PCB is mated with first electrical interface of the first PCB. In certain aspects, the first PCB includes a power cable interface adapted to receive a power cable connected to a PCI based solid-state storage device. In certain aspects the power control electronics include a dual stage constant current/constant voltage charging circuit and a load switch that controls power provided to the power cable from the supercapacitors. In certain aspects, the first PCB includes a two-way data cable interface adapted to receive a data cable connected to a PCI based solid-state storage device and to send and receive data signals over a connected data cable. In certain aspects, the plurality of supercapacitors are connected in series and wherein the second PCB includes an active balancing circuit adapted to regulate the voltage on each supercapacitor.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

FIG. 1 illustrates a solid-state storage accelerator according to one embodiment.

FIG. 2 illustrates file system architecture paradigms according to certain embodiments.

FIG. 3 illustrates a multi-node setup for HA according to an embodiment.

FIG. 4 illustrates a host system including a back-up power pack according to an embodiment.

FIG. 5 shows a power or charge supply card according to an embodiment.

FIG. 6 shows an embodiment of a back-up power pack.

FIG. 7 illustrates an embodiment of a load switch back-up power availability and charge control process.

FIG. 8 illustrates a temperature logging system according to an embodiment.

FIG. 9 illustrates a temperature logging process according to an embodiment.

FIG. 10 illustrates a memory card including one or more storage devices according to an embodiment.

FIG. 11 illustrates a back-up process according to an embodiment.

FIG. 12 illustrates a flowchart of the memory card and device driver controlled restore mechanism according to an embodiment.

FIG. 13 illustrates features of a power pack shell according to an embodiment.

FIG. 14 illustrates examples of possible temperature logging program output according to certain embodiments.

FIG. 15 illustrates a host system according to an embodiment including SSDs attached to a memory card.

FIG. 16A through FIG. 16P illustrates various views of a back-up power pack according to certain embodiments.

### DETAILED DESCRIPTION

Embodiments of the disclosure provide systems and methods that provide back-up power for data storage systems, in particular solid state storage devices, and other systems.

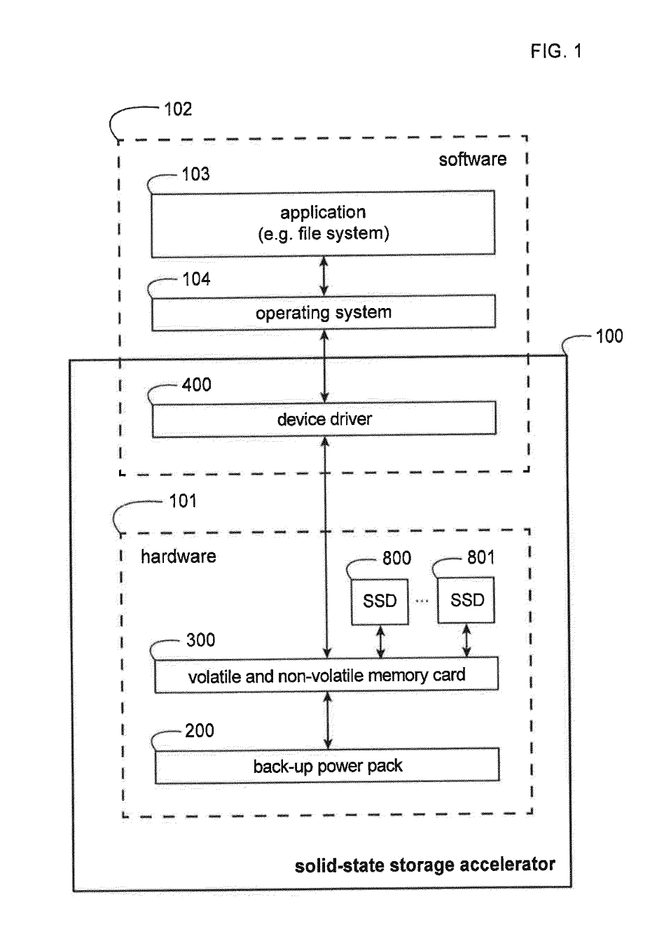

FIG. 1 illustrates a solid-state storage accelerator 100 according to one embodiment. In certain embodiments, the storage accelerator 100 is implemented as a PCIe plug-in card and will be discussed herein with reference to PCIe (Peripheral Component Interconnect Express) specification embodiments, although the embodiments may be implemented according to other specifications as would be apparent to one skilled in the art. For example, the data storage device or accelerator may be implemented as a device that connects to a host via a DIMM connector or other connector. As shown, the PCIe based solid-state storage accelerator 100 includes: a volatile/non-volatile memory card 300, a back-up power pack 200, a device driver 400, and optionally attached storage drives, e.g. SSDs (Solid-State Drive). The individual parts are combined to operate as an integrated system 100 spanning both hardware 101 and software 102 domains. Aspects of said system 100 are indivisible, if one or more of the three constituents, i.e. memory card 300, power pack 200, device driver 400, are removed or inoperable a loss of functionality may result, most notably the ability to perform as a NVRAM (Non-Volatile Random-Access Memory) drive. Said NVRAM function is independent of the one or more SSDs 800,801 which may be attached to the memory card 300. The storage accelerator 100 is accessed by the operating system 104 via the device driver 400 and targets storage related applications, typically a file system 103. The storage accelerator 100 is particularly effective when the file system 103 is based on a “hybrid storage pool” architecture.

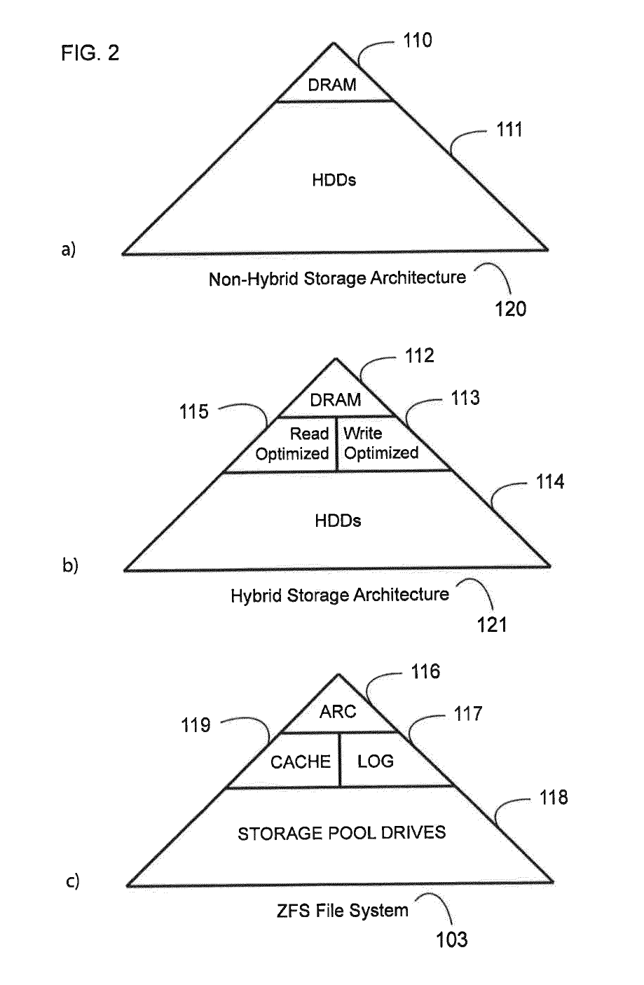

FIG. 2 illustrates file system architecture paradigms according to certain embodiments. The file systems 103 in FIG. 2b utilize a hybrid storage architecture 121 and have a central tenant, to natively leverage read and write optimized storage devices to accelerate the storage devices that comprise and determine the storage pool capacity. A hybrid storage pool is typically a collection of high capacity, low cost per bit, but high latency HDDs (Hard Disk Drive) 114 combined with storage devices which perform as read and write I/O (Input/Output) accelerators and leverage the host system 600 main memory 112 as a high performance cache. A read optimized 115 or write optimized 113 storage device advantageously services an I/O with lower latency and thus higher IOPS (I/O per second) compared to the same I/O being serviced by the pool HDDs. Said read or write optimized devices (typically) do not add to the pool capacity, but instead are used to increase overall pool I/O performance for specific workloads. A non-hybrid storage pool 120 (FIG. 2a) is one where the pool's IO performance is dictated solely by main memory caching 110 (if implemented) and the pool storage devices 111 (typically HDDs, less typically SSDs) and thus is commonly bound by the aggregated characteristics of said devices. In FIG. 2 the HDDs could be replaced with SSDs as long as the read/write optimized devices are still such relative to said SSDs and thus would keep intact the potential benefits of the hybrid storage pool architecture. Typically an SSD, as compared to an HDD, has lower capacity, higher cost per bit, and lower latency but delivers higher performance. Thus a non-hybrid storage pool composed of HDDs is typically advantageous for capacity and cost, but not performance and a non-hybrid pool composed of SSDs is typically advantageous for performance, but neither capacity nor cost. The intent of a hybrid storage pool is to garner, to the greatest degree possible, the capacity and cost benefits of a pool composed entirely of HDDs with the substantial performance benefits of a storage pool composed entirely of SSDs.

As shown in FIG. 2c, the ZFS file system 103 is a well known example of a hybrid storage architecture 121. ZFS supports a main memory cache known as the ARC (Adaptive Replacement Cache) 116 and both read and write optimized devices can be added to the storage pool drives 118 (typically HDDs). The read optimized devices are collectively referred to as L2ARC (Level Two Adaptive Replacement Cache) and are called cache devices 119. The write optimized device is called a log 117 and accelerates the ZFS Intent Log (ZIL). The ZIL is exclusively written to during normal operation and only read upon a host reboot. The L2ARC is a read cache and thus the majority of IO to cache devices are reads, L2ARC writes are purposely throttled (typically 8 MB/s) to reduce host CPU utilization. ZFS supports two types of “writes”, asynchronous and synchronous. Asynchronous writes do not require being written to stable storage prior to acknowledgment, but synchronous writes must be written to stable storage or risk loss in case of host failure. The ZIL stores all file system related system calls as transactions in host's main memory which is volatile. So if synchronous semantics apply (O_SYNC, fsync( ) . . . ), transactions must also be placed on a non-volatile log device, so in the event of a host failure each transaction can be replayed on the next reboot and not be lost.

The memory card 300 is presented to the operating system 104 via the device driver 400 as one or more storage devices, the number of which is determined either statically or dynamically. The memory card 300 can be configured and presented as either a single or multi-function PCIe endpoint and thus the memory card 300 can also support multiple functions, e.g. from one to eight PCIe functions. The memory card 300 storage devices comprise the combined functionality of an HBA (Host Based Adapter) and an SSD and characteristically provide the performance required to be defined as either read or write optimized. The memory card 300 implements a write optimized storage device using the on-board volatile and non-volatile memory and the physically separate power pack 200 The memory card 300 implements a read optimized storage device via a physically separate SSD attached to the memory card 300. In summary, ZFS advantageously uses both read and write optimized devices and the memory card 300 can provide said devices and do so using a single PCIe slot.

A PCIe plug-in card has both transmit and receive differential pairs and thus can be read and written simultaneously. The ZFS log device is exclusively written to during normal operation and the vast majority of the I/O traffic to the ZFS cache device is reads, thus the log/cache devices inherent traffic can be implemented with the simultaneous write/read capability of the PCIe protocol. Thus the overall intent of combining said devices onto a single memory card 300 is to approach the best case performance of using multiple PCIe plug-in cards with a single memory card 300. There are many flash based PCIe plug-in cards available, such as the Intel 910 Series and the latest DC P3700 and P3600 product lines. Said PCIe flash cards can be paired with the DDRdrive X1, to offer both read and write optimized devices with the latency and location (i.e. no pool traffic contention) benefits of PCIe, but require two empty PCIe slots. The potential benefits of a single memory card 300 providing both log and cache devices, compared to two separate plug-in cards, are as follows: lower PCIe slot power usage (one controller instead of two), lower cost (2.5″ SSDs are often less expensive than the PCIe equivalents of the same capacity), higher capacity (multiple external SSDs compared to a single PCIe flash card), a single device driver 400 when the memory card 300 is configured as a single function PCIe endpoint, and the freeing of an additional PCIe slot. Utilizing the PCIe slot to install a second memory card 300 enables ZFS to either stripe or mirror the log devices (provided by the memory card 300 NVRAM) and to double the number cache devices (provided by the memory card 300 attached SSDs) available. As demonstrated with the DDRdrive X1, an NVRAM only product, many ZFS workloads can approach a 2× increase in ZIL acceleration when two DDRdrive X1s are striped.

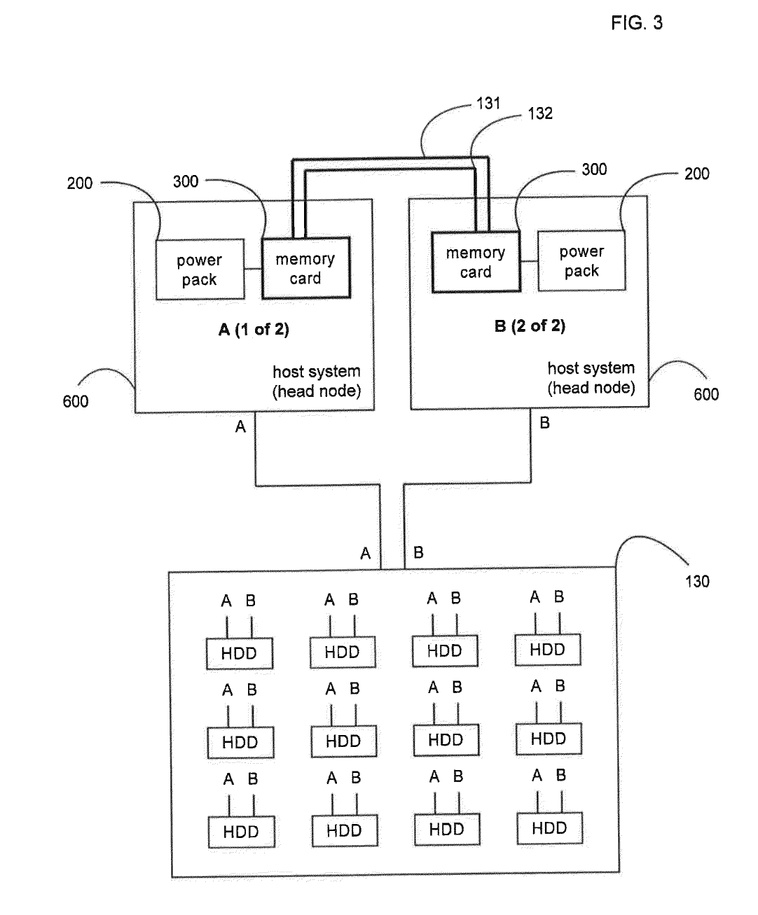

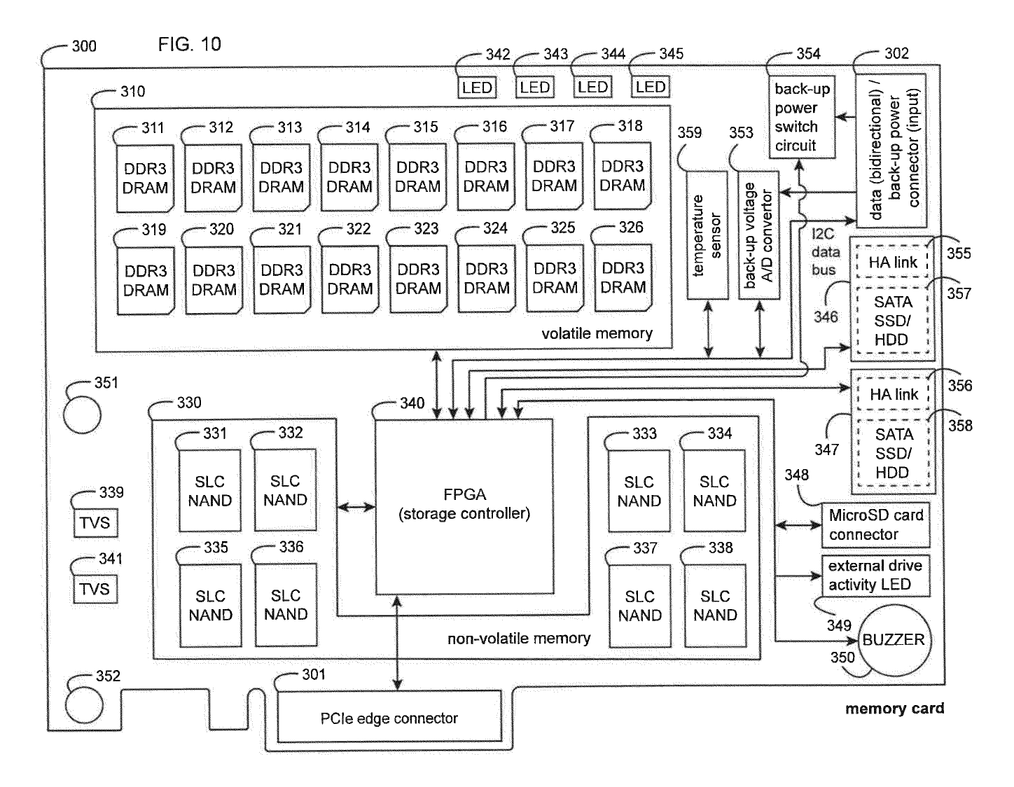

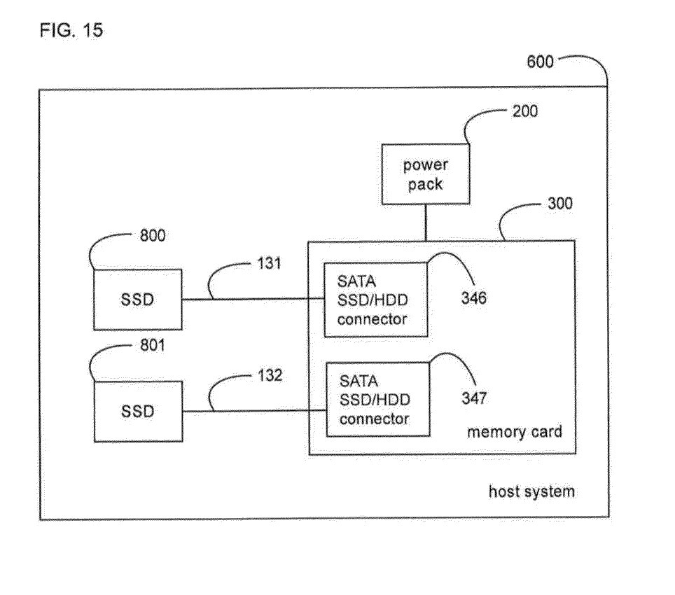

All ZFS based storage referred to in the prior paragraphs was configured as single node, but ZFS storage may also utilize a multiple node setup for HA (High Availability). FIG. 3 illustrates a multi-node setup for HA according to an embodiment. As shown in FIG. 3, at least two redundant host systems 600, each referred to in the context of HA as a head node. Each head node is attached to a storage pool configuration 130. Each head node is similarly configured with a memory card 300, a power pack 200, and a device driver 400. An HA configuration requires one or more of the memory card 300 external connectors 346-347 to be configured for card-to-card connections 355-356 (henceforth “HA links”) instead of SSD connections 357-358 as shown in FIG. 10 and illustrated in FIG. 15. How the FPGA (Field Programmable Gate Array) 340 transceivers and therefore external connectors are utilized, SSD or HA links, is determined by either statically loading the FPGA 340 bitstream or dynamically via a partially reconfigured bitstream. Statically reloading an FPGA 340 bitstream requires power cycling the memory card 300 host system 600 and thus results in host system 600 downtime, whereas partially reconfiguring a bitstream can be performed live on a memory card 300 and thus advantageously forgoes any host system 600 downtime. The same cables, e.g. SATA cables 131-132, otherwise used for SSD 800-801 attachment, can provide HA links by directly connecting two memory cards 300 utilizing a supported FPGA 340 transceiver based protocol. After a node failure, the cables enable the transfer of the volatile memory 310 (e.g. DRAM) contents from the memory card 300 in the failed head node to the memory card 300 in the surviving head node. Even though HA failures commonly involve power loss, the HA links work as described because each memory card 300 has a power pack 200 with appropriate energy to power the data transfer in its entirety. One or more memory cards 300, each configured with HA links, is a novel alternative to using a dual ported SAS SSD for ZFS based HA configurations requiring a log device. Said SAS SSD is often installed in the same JBOD (Just a Bunch Of Disks) storage chassis as the pool HDDs, as the SAS SSD requires the same head node (e.g. A and B) attachments. The SAS SSD JBOD mounting disadvantageously forces the SAS SSD I/O to contend with all other pool HDD I/O traffic. I/O contention between the storage pool HDDs and the SAS SSD based log device slows both. Disadvantageously, the base I/O latency is expected to increase when using a JBOD mounted SAS SSD compared to a memory card 300. Whereas the memory card 300 implemented log device requires but a single hop for each host system 600 I/O (CPU to memory card 300), the SAS SSD requires three hops (CPU to HBA to JBOD chassis to SAS SSD). The HA link capability brings forth the memory card 300 single node benefits of reduced “single hop” latency and pool I/O contention avoidance to HA configurations.

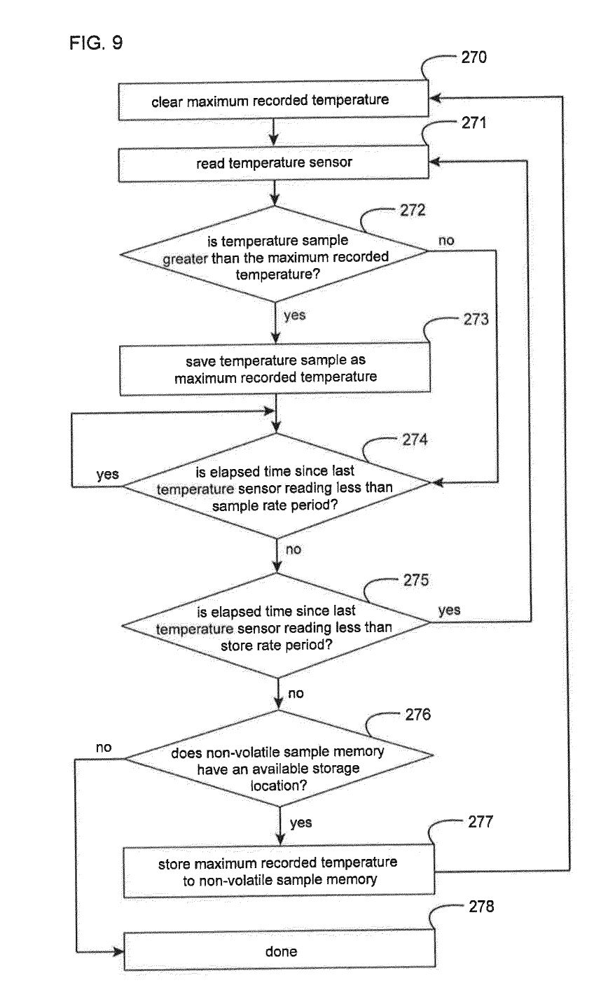

As discussed above, the FPGA 340 has multiple transceivers externally accessible via physical connectors. In the FIG. 9 embodiment, said connections are implemented with industry standard SATA connectors 346-347 which are either statically or dynamically configured to render combinations of SSD attachment 357-358 and/or HA links 355-356. Partial reconfiguration is the ability to reconfigure one part of the FPGA 340 while the remaining parts continue to operate unaffected, thus partial reconfiguration can beneficially maximize the FPGA 340 feature set while minimizing the utilized resources. Irrespective of the transceiver's end purpose, FPGA 340 resources are required to implement said purpose and are of finite quantity. One alternative to partial reconfiguration is to increase on-chip resources to the point where all intended partial reconfigurations can exist simultaneously. FPGA 340 variants can be sourced with increased resource allocations, in the FIG. 9 embodiment the FPGA 340 (e.g. an Altera Arria V GZ, part number 5AGZE1) contains ALMs (Adaptive Logic Module), M10K memory blocks, and 12.5 Gbps transceivers. Examples of suitable upgrades include the 5AGZE3, 5AGZE5, or 5AGZE7, each potentially supporting multiple configurations of SSD and/or HA links in a single statically generated bitstream. But, the memory card 300 novel use of partial reconfiguration can potentially avoid upsizing the FPGA 340 to a more expensive and higher power FPGA. Reducing power utilization is important considering the power pack 200 finite capacitance and bounded charge completion time. The memory card 300 use of partial reconfiguration is not limited to transceiver configuration and can be used whenever additional functionality is required, but without forcing an upsizing of the FPGA 340. Also of note, to statically load a new FPGA 340 bitstream requires power cycling the memory card 300 and most likely the host system 600 in which the memory card 300 is installed. Partial reconfiguration avoids the power down requirement and thus advantageously increases server up-time.

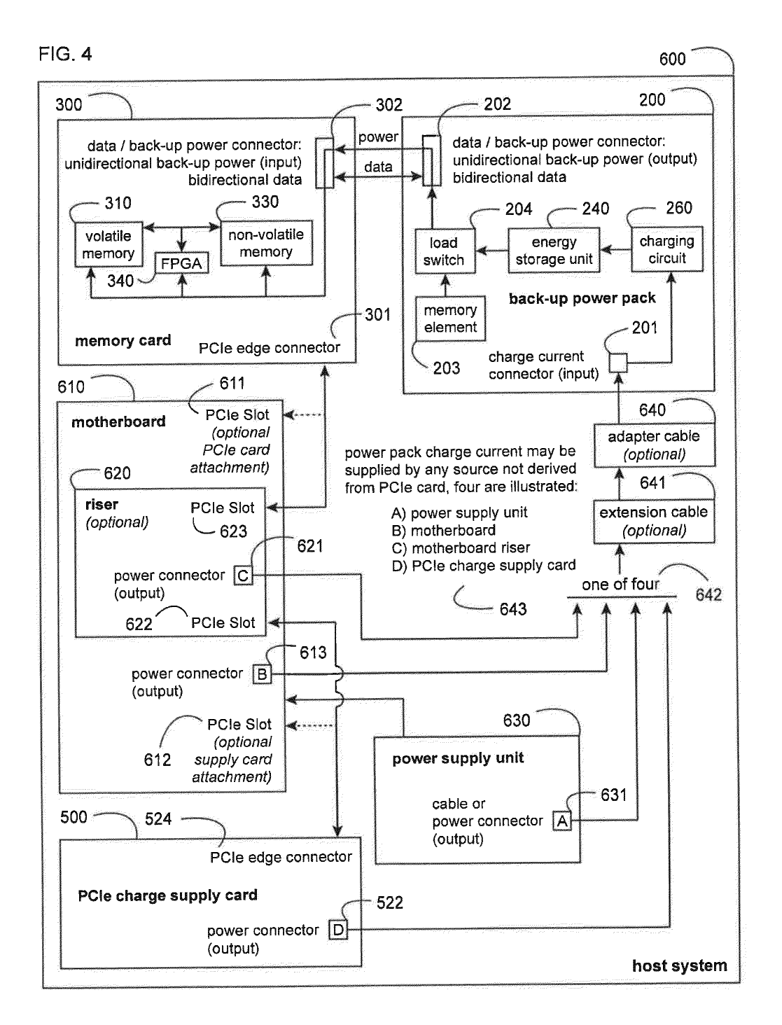

FIG. 4 illustrates a host system 600 including a back-up power pack 200 according to an embodiment. The constituent parts of host system 600 specific to power pack 200 charging as shown in FIG. 4 include a motherboard 610, an optional motherboard riser 620, a power supply unit 630, a memory card 300, a power pack 200, and an optional PCIe charge supply card 500. As shown, power pack 200 includes a charging circuit 260, an energy storage unit 240, and a load switch 204. A first connection 201 enables connection of a charge current source 642 to charging circuit 260, and a second connection 202 enables connection of energy storage unit 240, typically via load switch 204, to memory card 300. The charge current source 642 is selected from multiple potential charge current sources. Typically the charge current source 642 provides a 12V power supply, however other voltages may be provided. In certain aspects, only one charge current source 642 may be connected, at any given time, to the charging circuit 260 to charge the energy store 240 via the charge current connection 201. Connection 201 may include a power connector as will be discussed below in more detail. Similarly, connection 202 may include a power connector as will be discussed in more detail below. The load switch 204 and memory element 203 determine whether the back-up power contained in the energy storage unit 240 is coupled to the data/back-up power connection 202 (so as to provide power to attached memory card 300 via a power connector). The memory card 300 contains volatile memory 310, non-volatile memory 330, an FPGA 340, and a data/back-up power connector 302 input which is attached to the data/back-up power connection 202.

A motherboard riser 620 is typically used to allow a full height PCIe card to be installed in a 2U chassis form factor, which otherwise would only support low profile PCIe cards. The riser 620 reroutes the PCIe slots to a typically proprietary PCB oriented perpendicular to the motherboard 610 so that the PCIe card is installed in parallel to the motherboard 610, thus allowing a full height card to fit in a 2U chassis form factor.

The power pack 200 novel use of a charge current source 642, not derived from the memory card 300 in which back-up power is provided, enables a plurality of potential charge current sources. “Not derived from the memory card 300” describes the charge current's path as it travels from the origin (i.e. charge current source 642) to the final destination (i.e. power pack 200). The power pack 200 is purposefully architected so that said charge current completely circumvents the memory card 300. The benefits of memory card 300 charge current circumvention include the following: maximizing the potential charge current source magnitude and thus minimizing the power pack 200 charge completion time, maximizing the potential current available for memory card 300 functionality and thus maximizing the magnitude of said functionality (e.g. increasing storage capacity), minimizing the potential current used by the memory card 300 and thus minimizing the required power pack 200 charge completion time, minimizing the potential current used by the memory card 300 and thus minimizing the required PCIe slot power allotment (e.g. enabling a lower PCIe slot power limit, e.g. 75 W to 25 W), and minimizing the potential current used by the memory card 300 and thus minimizing the required memory card 300 cooling requirements (e.g. decreasing heatsink size and cost).

The charge current circumvention of the memory card 300 results in a minimum two connection power pack 200 configuration, an alternative single connection configuration is possible if the charge current travels through the PCI card to the power pack 200 but that requires foregoing the above benefits.

Four of the potential charge current sources 643 are detailed in FIG. 4 and are as follows: a power supply unit connection 631, a motherboard power connection 613, a motherboard riser power connection 621, or a PCIe charge supply card (henceforth “supply card”) connection 522. The power supply unit connection 631 can provide either permanently affixed cables or end-user replaceable cables via a power supply unit connector 631. Any of the four charge current sources 643 may require an optional extension cable 641 and/or an optional adapter cable 640 to complete the power pack 200 charge current connection. An adapter cable 640 enables a charge current connection in instances where the cable receptacle originating from the charge current source 642 is not otherwise mateable with the charge current connector. In cases where the same charge current power connector is used by different charge current sources, the cable used to connect to the power pack 200 may be the same. In other cases where the charge current power connector is different, the cable coupling the charge current source to the power pack 200 may be different.

The motherboard 610 includes one or more PCIe slots 611-612 supporting installation of one or more memory card 300 via a PCIe edge connector 301 and/or one or more PCIe charge supply cards 500 via a PCIe edge connector 524. The optional motherboard riser 620 includes one or more PCIe slots 622-623 supporting installation of one or more memory card 300 and/or one or more supply cards 500. The PCIe CEM (Card Electro Mechanical) Specification defines a specific power budget/limit for each PCIe slot 611-612, 622-623. Said limit may be further constrained by the host system 600 manufacturer, often to lower the internal ambient air temperature. Overall the memory card 300 functionality should be bound by said limit or risk host system 600 incompatibility.

The host system 600, in which the memory card 300 and power pack 200 are installed, can be powered by a multitude of different power supply units 630. Certain server vendors (e.g. Supermicro) provide host power supply units 630 that use industry standard cables/receptacles to power devices internal to said chassis, others (e.g. Intel, Dell, HP) typically connect said power supply unit 630 to the motherboard 610 using a proprietary mechanism. Thus host system 600 motherboard/riser layouts and power connector configurations vary greatly between vendors and even between models from the same vendor, resulting in a plurality of possible power connector configurations. Four exemplar embodiments of the charge current sources 643 as illustrated in FIG. 4 will be detailed next.

In a first embodiment, the power supply unit 630 in a host system 600 (e.g. Supermicro SC826, SC846, or SC847) is an optimum charge current source 642. A receptacle (e.g. Molex SD-8981-4P) can be directly mated to an on-board header (e.g. Molex SD-8981-4R1) in certain power pack 200 embodiments and coupled via an adapter cable 640 to the header 201 (e.g. Molex SDA-70555) on-board the power pack 200 embodiment shown in FIG. 4.

In a second embodiment, a host system 600 (e.g. Intel 2U R2000WT/GZ/GL) has a proprietary power supply unit 630 to motherboard 610 attachment and therefore a motherboard power connector 613, and not the power supply unit 630, provides the charge current source 642. This embodiment is illustrative of using a motherboard 610 power connector 613 and not a riser 620 power connector 621, even though the PCIe slots are located on the riser 620. The motherboard 610 provides two industry standard 4 pin connectors (e.g. Molex 39-28-1083) which can be coupled to the power pack 200 via an adapter cable 640.

In a third embodiment, a host system 600 (e.g. Dell PowerEdge R720 2U rack server) exemplifies a power supply unit 630 to motherboard 610 to riser 620 power connector 621 which provides the charge current source 642. On each of the motherboard 610 risers 620 is a Dell proprietarily wired but otherwise standard 8 pin connector (e.g. Molex 39-28-1083), said connector is repurposed via an adapter cable 640 to charge the power pack 200. This embodiment is illustrative of a power connector 621 being located on the riser 620 and not the motherboard 610 when the PCIe slots 622-623 are located on the riser 620.

In a fourth embodiment, the charge current is provided via a power supply unit 630 to motherboard 610 or riser 620 to supply card 500 to power pack 200 coupling. The supply card 500 advantageously enables power pack 200 use when the power supply unit 630 is proprietary (i.e. appropriate cable/receptacle is unavailable) and/or the motherboard 610 or riser 620 lacks an available and/or suitable (e.g. correct voltage and/or current capacity) power connector, but does have an available PCIe slot 611-612, 622-623 to populate. A motherboard 610 or riser 620 has a finite number of PCIe slots and therefore each slot is a valued resource. An advantage of the supply card 500, relative to other current sources, is the supply card 500 contains on-board low inductance/ESR (Equivalent Series Resistance) MLCC (Multi-Layer Ceramic Capacitor) decoupling capacitors. Said capacitors may advantageously buffer and thus benefit the stability of the host systems 600 12V power rail.

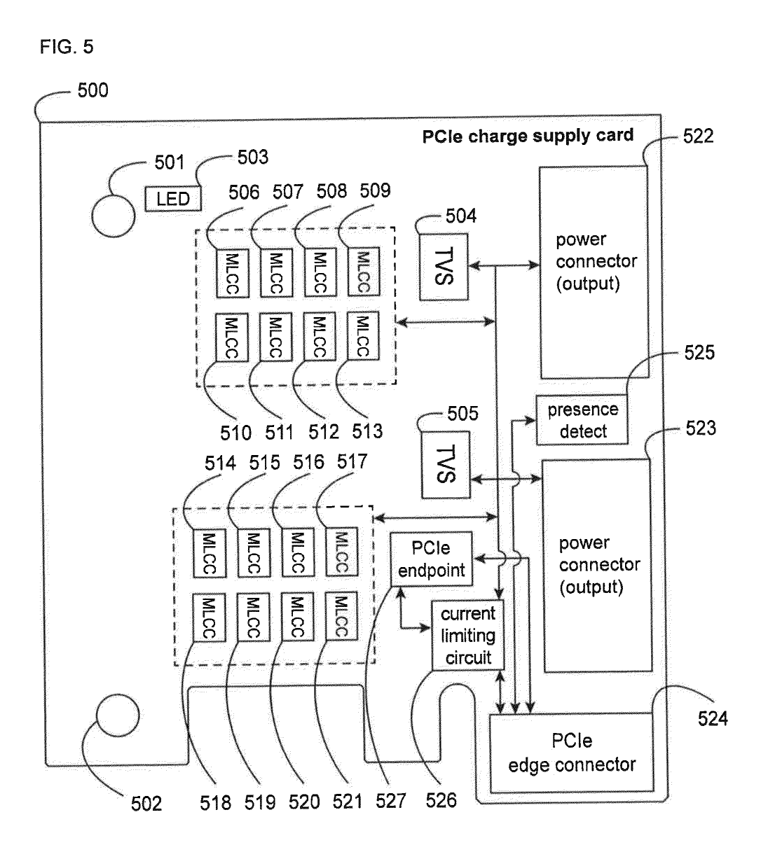

FIG. 5 shows a supply card 500 according to an embodiment. Supply card 500 in one embodiment is a four layer (e.g. 2 oz internal copper fabrication) PCB (Printed Circuit Board) which uses an PCIe edge connector 524 comprising either x1, x4, x8, or x16 lane sizes. The supply card 500 may provide a charge current source to one or more power pack 200 if the mating PCIe slot has a sufficient power budget/allotment. The supply card 500 can have one or more headers 522,523 (e.g. Molex SDA-70555 or Molex SD-8981-4R1) protected by one or more TVS (Transient Voltage Suppressor) devices 504, 505 (e.g. SMCJ12A or SMBJ12A) and bypassed with one or more banks 506-513, 514-521 of decoupling capacitors (e.g. eight MLCC/22uF/25V/1210 components). A green LED 503 indicates (when lit) the host motherboard/riser is powered. In certain aspects, supply card 500 supports a PCIe low profile metal bracket with matching mounting holes 501, 502. In certain aspects, supply card 500 has a populated or unpopulated zero ohm resistor 525 (default is populated) to connect or disconnect PCIe pins A1 and B17 allowing support of the PCIe CEM Specification “presence detect” feature. Said feature is used by certain motherboards during POST (Power On Self-Test) to detect the presence or absence of an installed PCIe plug-in card. The on-board current limiting circuit 526 enables support of one of more power packs 200 while still respecting the PCIe slot power limits. Circuit 526 can be configured to support the current PCIe CEM Specification power limits: PCIe x1 slot 10 W and 25 W limit, PCIe x8/x16 slot 25 W limit, and the PCIe x8/x16 GPU slot 75 W limit (3.3V at 3 A and 12V at 5.5 A). The PCIe endpoint 527 may be implemented as either an FPGA, microcontroller, or ASIC and communicates PCIe power states, status, and requirements to the motherboard 610 PCIe root complex. Endpoint 527 could also enable classifying itself as a GPU (Graphics Processing Unit) to thus enable the maximum PCIe slot power limit of 75 W.

In one embodiment, the power pack 200 is a self-charging and self-regulated power source comprised of two interconnected PCBs. The unique perpendicular orientation and attachment mechanism of the PCBs is the basis for the power pack 200 unique form factor and mechanical attributes, which advantageously includes a 2.5″ SSD mounting pattern compatible form factor to maximize host chassis mountability and an end-user accessible replacement of the energy storage unit. The power pack 200 form factor is important, as it may determine not only where but if the power pack 200 can be successfully installed. The memory card 300 NVRAM function necessitates power pack 200 attachment, thus power pack 200 fitment underlies the viability of the memory card 300 itself.

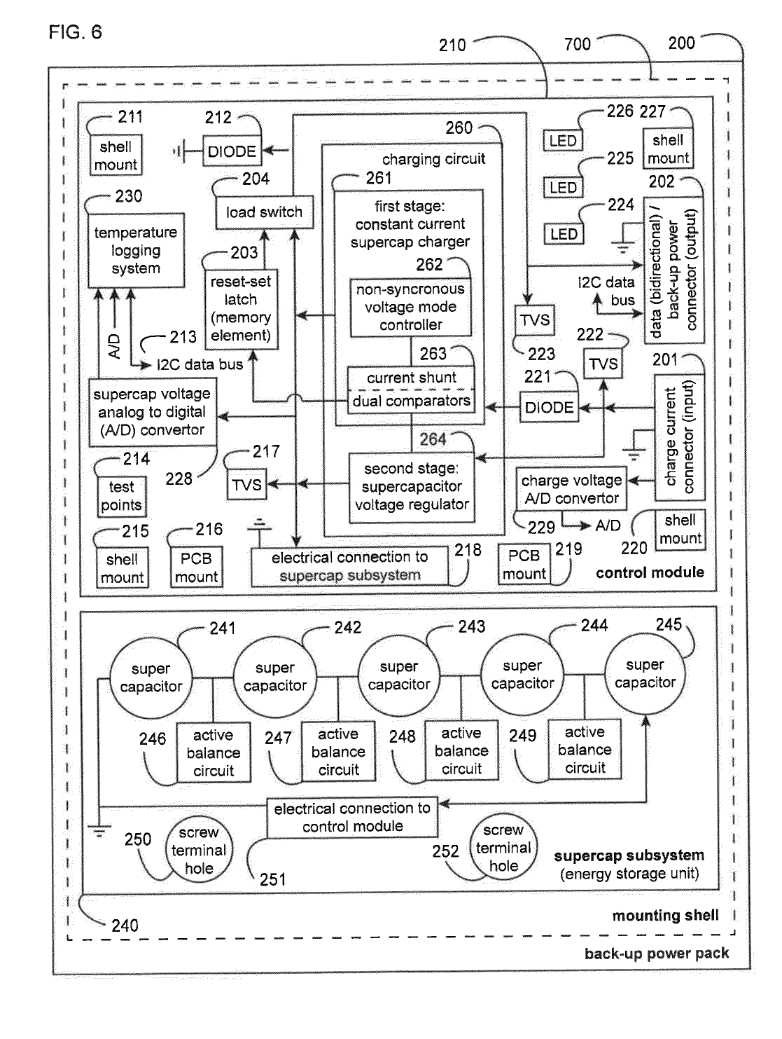

FIG. 6 shows an embodiment of a power pack 200. Power pack 200 includes a primary and secondary PCB. The primary is designated the control module 210 and includes: a charge current connector input 201 where the charge current circumvents the memory card 300, a dual stage charging circuit 260 with the first stage 261 a constant current circuit and the second stage a constant voltage circuit 264, a load switch 204 and a RS (Reset-Set) latch 203 (also known as the memory element) which controls and protects the integrity of the back-up power delivery, a temperature logging system 230, a data/back-up power connector 202 which outputs back-up power to the memory card 300 and a data bus 213 (e.g. I2C bus) to facilitate bidirectional memory card 300/power pack 200 communication, and an electrical connection to the supercapacitor (also referred to herein as “supercap”) subsystem 218. The charging circuit is further comprised of a first stage non-synchronous (e.g. IRF7726/B340A) voltage mode controller 262 (e.g. TPS40200) integrated with a current shunt monitor with dual comparators 263 (e.g. INA206) to create a unique constant current charging circuit. The charging circuit further comprises a second stage charger implemented by a low-noise linear regulator (e.g. TPS7A4501) to minimize the ongoing heat generated by the continual supercap voltage regulation. The control module 210 also facilitates the monitoring of key power pack 200 voltages by way of a supercap A/D (Analog to Digital) voltage convertor 228 and a charge current A/D voltage convertor 229. The control module 210 also displays key modes of operation via three LEDs: a lit green LED 224 to indicate the charge current source 642 is attached, a lit yellow LED 225 to indicate the first stage charging is in progress, and a lit red LED 226 to indicate the load switch 209 (e.g. TPS2590) has encountered a fault condition (e.g. an electrical short) and stays lit until said condition is remedied. The power pack 200 includes a protective shell 700 (e.g. fabricated from aluminum) which is affixed to the control module 210 with four screw terminals 211, 215, 220, 227 (e.g. Keystone 7774). In certain aspects, the supercap subsystem 240 is physically adhered to the control module 210 with two screw terminals 216, 219 (e.g. Keystone 7774). The power pack 200 ability to withstand and protect against transient electrical events is supported by the following: a TVS device 222 (e.g. SMCJ12A) protecting the charge current input, a TVS device 223 (e.g. SMCJ12A) protecting the back-up power output, a TVS device 217 (e.g. SMCJ12A) protecting the load switch input from positive voltage spikes, and a Schottky diode 212 (e.g. B340A) protecting from inductive negative voltage spikes on the load switch output. For diagnostic measurements and burn-in purposes the control module 210 has four test points (e.g. Keystone 5015) 214.

The memory card 300 is powered by the host system 600 during normal operation and only switches over to the power pack 200 if the host power fails or is removed. The load switch 204 and related circuitry is located on the control module 210 and serves two purposes. First, it provides short circuit protection for the memory card 300 and the power pack 200. Load protection is accomplished in certain aspects by a non-current limiting fault threshold, a hard current limit threshold, and a fault timer. The lower non-limiting current threshold advantageously supports the memory card 300 drawing higher currents for short periods. If a fault condition does occur, such as the hard current limit being exceeded the red LED 226 is illuminated. Second, the load switch 204 provides precise control on whether the back-up power provided by the power pack 200 is made available to the memory card 300. Said control is implemented with a RS latch 203 (e.g. SN74LVC2G02) and related circuitry. The load switch 204 is either enabled or disabled by the output of the RS latch 203. Each of the two inputs to the RS latch 203 is provided by a voltage comparator 263 which continuously monitors the supercap subsystem 204 voltage. Both voltage comparators 263 are operational as long as either the host system 600 power is present or the supercap subsystem 204 is at least charged to the minimum comparator 263 working voltage (typically 2.7V). In certain aspects, both voltage comparator 263 inputs are generated using resistor dividers to scale the supercap subsystem 204 voltage to the comparator 263 reference voltage. One comparator 263 continuously monitors if the predefined first stage charge to voltage has been reached and when true will set the RS latch 203 accordingly to turn on the load switch 204. The other comparator 263 continuously monitors if the predefined power pack cutoff voltage has been reached and when true will set the RS latch 203 accordingly to turn off the load switch 204. The power pack 200 cutoff voltage is always less than and not equal to the charge completion voltage, thus nominally (i.e. the operating level at which the hardware device was designed to operate) the voltage comparators 263 can never both output true at the same time. This is notable as the RS latch 203 should not have both inputs be set at the same time during normal operation. The RS latch 203 performs a memory element function which provides load switch 204 control as long as the minimum RS latch 203 working voltage (typically 1.5V) is satisfied.

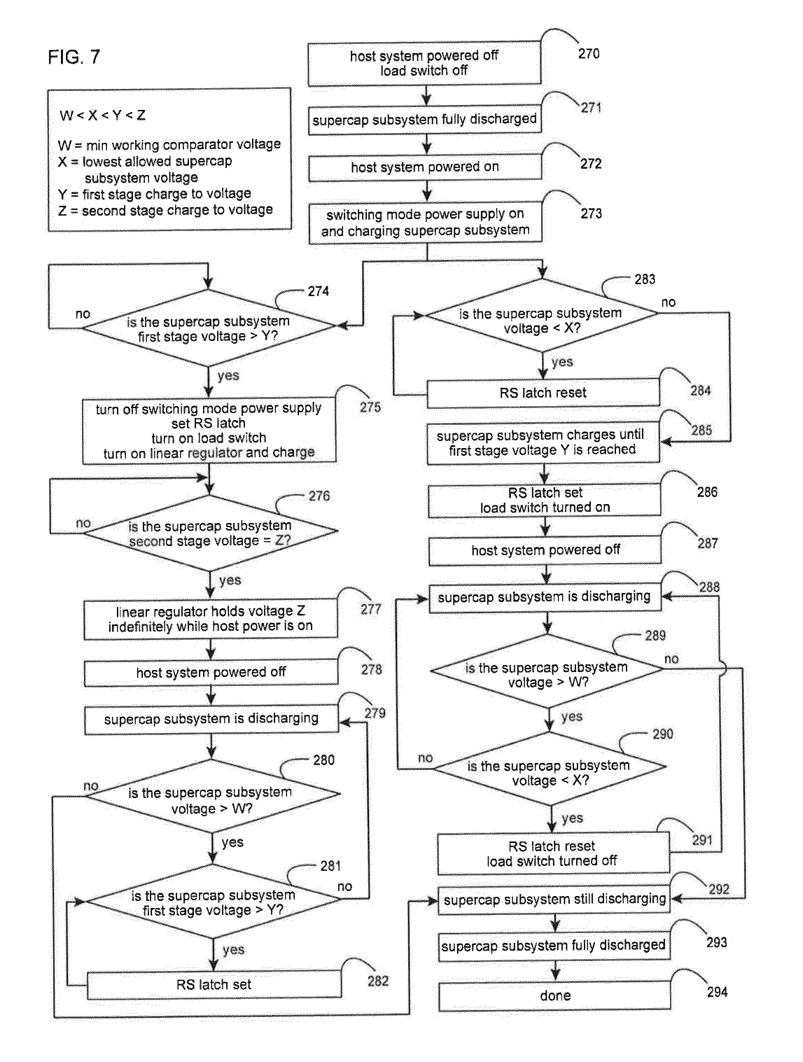

FIG. 7 illustrates an embodiment of a load switch 204 back-up power availability and charge control process. In certain aspects, there are four power pack 200 voltages: a minimum comparator 263 working voltage designated with the letter ‘W’, a power pack cutoff voltage designated with the letter ‘X’, a first stage charge to voltage designated with the letter ‘Y’, and a second stage charge to voltage designated with the letter ‘Z’. Said voltages are interrelated as follows: W is less than X, X is less than Y, and Y is less than Z. The voltage comparator 263 which compares the supercap subsystem 204 voltage to the predefined first stage charge to voltage will trigger the load switch 204 to turn on when Y is reached. The voltage comparator 263 which compares the supercap subsystem 204 voltage to the predefined power pack cutoff voltage will trigger the load switch 204 to turn off when X is reached. The process starts with step 270, in which the host system 600 is powered off and the load switch 204 is turned off. In step 271, the supercap subsystem 204 reaches a fully discharged state. In step 272, the host system 600 is powered on. In step 273, the first stage of the charging process, which is the switching mode power supply, is initiated and the supercap subsystem 204 starts to charge. In step 274, it is determined if the supercap subsystem voltage is greater than the first stage charge to voltage. If the supercap subsystem voltage is greater than the first stage charge to voltage then the process continues to step 275. If the supercap subsystem voltage is not greater than the first stage charge to voltage then step 274 is repeated. In step 275, the switching mode power supply is turned off, the RS latch is set, the load switch is turned on, and the linear regulator is turned on to initiate the second stage of the supercap subsystem charging process. In step 276, it is determined if the supercap subsystem voltage has reached the second stage charge to voltage. If the second stage charge to voltage has been reached then the process continues to step 277. If the second stage charge to voltage has not been reached then step 276 is repeated. In step 277, the linear regulator regulates the supercap subsystem voltage to the predefined second stage charge to voltage. In step 278, the host system 600 is powered off. In step 279, the supercap subsystem discharges at its self-discharge rate. In step 280, it is determined if the supercap subsystem voltage is greater than the minimum comparator working voltage. If the supercap subsystem voltage is greater than the minimum comparator working voltage then the process continues to step 281. If the supercap subsystem voltage is not greater than the minimum comparator working voltage then the process continues to step 292. In step 281, it is determined if the supercap subsystem voltage is greater than the first charge to voltage. If the supercap subsystem voltage is greater than the first charge to voltage then the process continues to step 282. If the supercap subsystem voltage is not greater than the first charge to voltage then the process returns to step 279. In step 282, the RS latch is set and the process returns to step 281. In step 283, it is determined if the supercap subsystem voltage is less than the power pack cutoff voltage. If the supercap subsystem voltage is less than the power pack cutoff voltage then the process continues to step 284. If the supercap subsystem voltage is not less than the power pack cutoff voltage then the process continues to step 285. In step 284, the RS latch is reset and the process returns to step 283. In step 285, the supercap subsystem continues to be charged until the first stage charge to voltage is reached. In step 286, the RS latch is set and the load switch is turned on. In step 287, the host system is powered off. In step 288, the supercap subsystem discharges at its self-discharge rate. In step 289, it is determined if the supercap subsystem voltage is greater than the minimum comparator working voltage. If the supercap subsystem voltage is greater than the minimum comparator working voltage then the process continues to step 290. If the supercap subsystem voltage is not greater than the minimum comparator working voltage then the process continues to step 292. In step 290, it is determined if the supercap subsystem voltage is less than the power pack cutoff voltage. If the supercap subsystem voltage is less than the power pack cutoff voltage then the process continues to step 291. If the supercap subsystem voltage is not less than power pack cutoff voltage then the process returns to step 288. In step 291, the RS latch is reset and the load switch is turned off and the process returns to step 288. In step 292, the supercap subsystem is still discharging at its self-discharge rate. In step 293, the supercap subsystem reaches a fully discharged state and the process ends 294.

The secondary PCB is designated the supercap subsystem 240 (also known as the energy storage unit) and contains an end-user accessible FRU (Field Replaceable Unit) comprised of multiple (e.g. five 110 F) supercapacitors 241-245 (e.g. HB1860-2R5117-R) connected in series. Supercapacitors 241-245 are connected in series and utilize active balancing circuits 246-249 with low power op-amps (e.g. LM321) to keep the voltages of the individual supercapacitors equal during the charging process and thus protect against supercapacitor damage stemming from overvoltage. Also, a supercapacitor's nominal voltage (e.g. 2.5V) is derated to increase longevity and/or increase the allowable ambient temperature. Voltage derating is defined as charging and then holding a supercapacitor to a voltage lower than the nominal voltage. The supercap subsystem 240 has PCB holes 250, 252 to enable fastening to the control module 210 PCB mounting terminals, and an electrical connection to the control module 251.

The control module 210 is electrically connected to the supercap subsystem by a low inductance through-hole 14 pin header (e.g. PRPC014SAAN-RC) and a right-angle through-hole 14 pin receiver (e.g. PPPC141LGBN-RC) pair. The inherent inductance of said 14 pin receiver/header pair is further reduced by assigning 7 pins to carry the supercapacitor current (SC) interleaved with 7 ground (GND) pins. Said pin interleaving is as follows: pin 1 is GND, pin 2 is SC, pin 3 is GND, pin 4 is SC, pin 5 is GND, pin 6 is SC, pin 7 is GND, pin 8 is SC, pin 9 is GND, pin 10 is SC, pin 11 is GND, pin 12 is SC, pin 13 is GND, pin 14 is SC. The inductance reduction is precipitated by the supercapacitor charge/discharge currents flowing in parallel but opposite directions to the resulting ground current, thus exacting a degree of inductance cancellation.

A specific prior power pack 200 embodiment utilizes two pin headers (e.g. Molex SDA-70555) as the back-up power connectors on both the memory card 300 and power pack 200 and a bidirectional cable (e.g. I2C) attached to the power pack 200 via a header (e.g. Hirose DF13-2P-1.25DSA). The FIG. 6 embodiment combines what was the physically separate power and I2C cables of the prior embodiment into a single data/back-up power cable that uses 6 circuit receptacles (e.g. Molex SD-70066) on both cable ends and which mates to 6 circuit headers (e.g. Molex SDA-70555) on-board the power pack 200 and memory card 300. Said power cable is comprised of six wires where the terminals are typically soldered to a silver-plated 9/32 stranded 20 AWG (American Wire Gauge) copper wire with extruded Teflon insulation capable of a minus 65 C to 200 C temperature range.

In the FIG. 6 embodiment, the supercap subsystem 240 is comprised of supercapacitors, which have energy storage characteristics advantageous to alternative battery technologies, but they still have a finite lifetime. The end-of-life or failure mode of a supercapacitor is a decrease in capacitance and/or increase in ESR (Equivalent Series Resistance) both of which can be directly affected by ambient temperature. For example, manufacturer's guidelines state raising ambient temperature by 10 degree Celsius will decrease supercapacitor lifetime by a factor of two and reducing temperature by 10 degree Celsius will double expected lifetime. Thus ambient temperature is an important factor in determining a product warranty period and the terms and conditions of said warranty. Typically one of those conditions is a maximum ambient temperature allowed. A best case scenario is to have access to a statistically significant number of ambient temperature samples which then allow meaningful analysis of said samples. An alternative is to permanently store an insufficient sample size such as a single maximum recorded temperature over the life of a product.

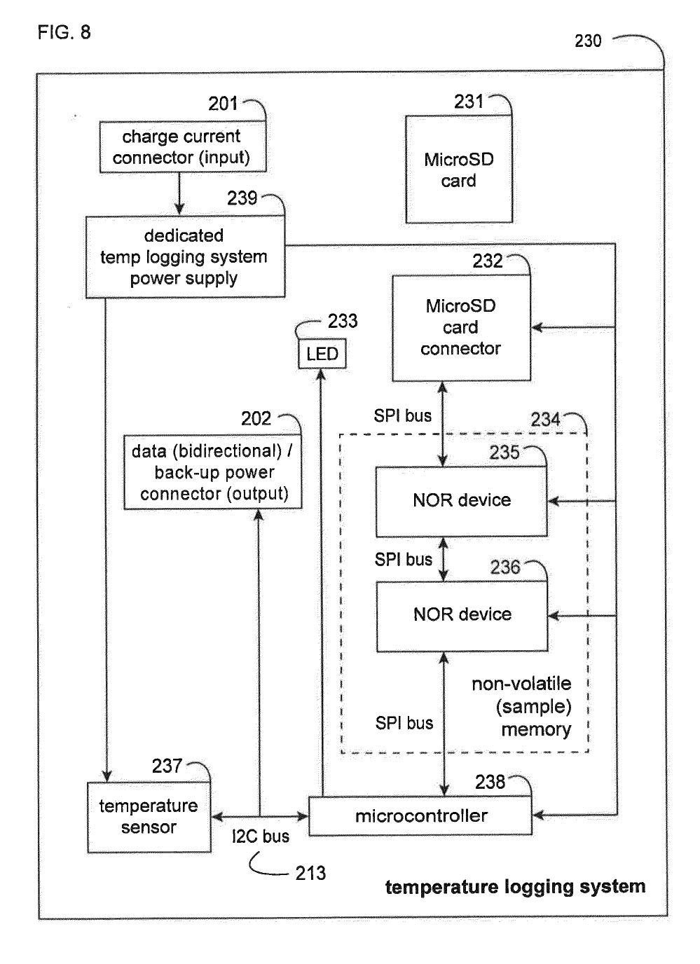

The temperature logging system 230 includes a temperature sensor 237 (see FIG. 8) which samples the ambient temperature of the power pack 200 at a sample rate and then stores the maximum recorded temperature to the non-volatile sample memory 234 at a store rate. Said maximum recorded temperature is the maximum temperature of all temperatures sampled since the last maximum recorded temperature was stored.

The temperature logging system 230 includes a microcontroller 238 (See FIG. 8) that executes a temperature logging process, an embodiment of which is displayed in FIG. 9. The maximum temperature sampled since the last sample was stored to non-volatile sample memory is saved as the maximum recorded temperature. In step 270, the maximum recorded temperature is cleared. In step 271, the temperature sensor is read resulting in a temperature sample. In step 272, the temperature sample is compared to the maximum recorded temperature. If the temperature sample is greater than the maximum recorded temperature then the process proceeds to step 273. If the temperature sample is less than or equal to the maximum recorded temperature then the process proceeds to step 274. In step 273, the temperature sample replaces the prior maximum recorded temperature. In step 274, the elapsed time since the last temperature sensor reading is compared to the sample rate period. If elapsed time is greater than or equal to the sample period then the process continues to step 275. If elapsed time is less than the sample rate period then step 274 is repeated. In step 275, the elapsed time since the last temperature sensor reading is compared to the store rate period. If elapsed time is greater than or equal to the store period then the process proceeds to step 276. If elapsed time is less than the store rate period then the process returns to step 271. In step 276, it is determined if the non-volatile sample memory has an available storage location. If the non-volatile sample memory has a storage location available the process continues to step 277. If the non-volatile sample memory does not have an available storage location then the process ends 278. In step 277, the maximum recorded temperature is stored to non-volatile sample memory and the process returns to step 270.

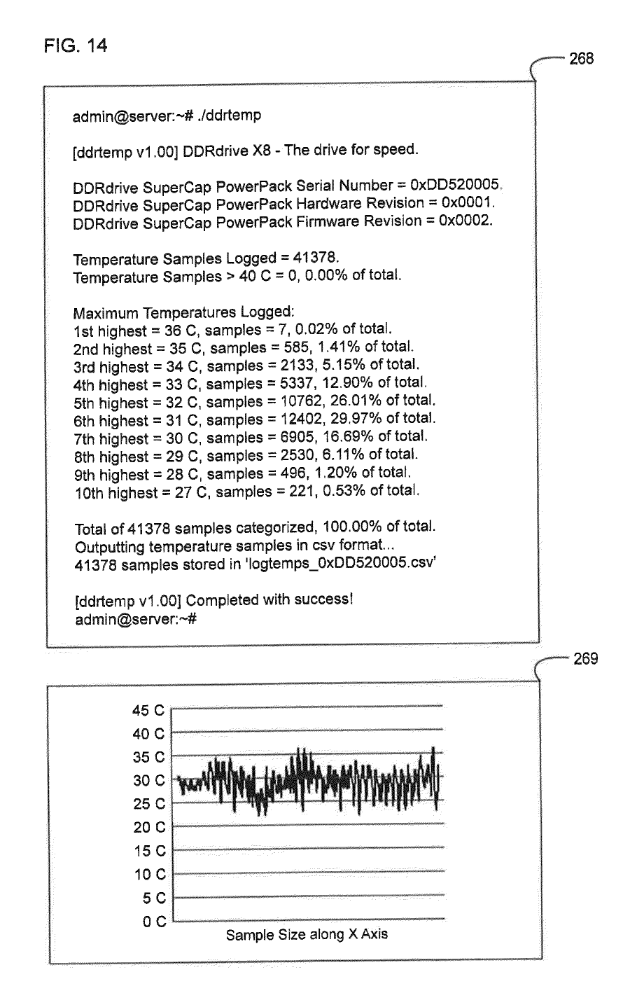

Every sample stored is available for future access/analysis and samples are continually stored until the non-volatile sample memory 234 capacity is fully utilized. In certain aspects, no prior sample is overwritten during sample storage to non-volatile memory, but the entire non-volatile sample memory may be erased when a special command sequence is received. The embodiment uses a store rate and a non-volatile sample capacity to enable samples to be continually stored for a time period that exceeds the warranty period. Most non-volatile memories have erase/program cycle limitations and a data retention period that is finite, thus the non-volatile memory should be selected to support the store rate, the warranty period, and an acceptable period for analysis following said warranty period. Analyzing the stored temperature samples is best supported by enabling said samples to be conveniently retrieved from the power pack 200. To that end, inserting a portable computer readable medium 231 into an attached connector 232, e.g. an industry standard MicroSD card formatted with the FAT32 (File Allocation Table) file system, automatically initiates a copy of the logged temperature samples from the non-volatile sample memory 234 to a file located on the medium 231, e.g. MicroSD card. During said copy an LED 233 (e.g. orange) is lit to indicate the copy is in progress. The LED 233 turns off to indicate the copy is complete and the medium 231 can be safely removed from the connector 232. In certain embodiments, the connector 232 is advantageously located at the edge of the control module 210 PCB allowing convenient medium 231 insertion and removal “in the field” by the end-user. The medium 231 can then be inserted into a computer system or reader that supports the FAT32 file system to perform analysis. A command line utility program is supported that displays said samples after categorizing by highest temperature as shown in the sample command line utility program output 268 (e.g. sample rate is one second/store rate is one minute) in FIG. 14. Said command line utility program also outputs the samples in a comma-separated value file format (.csv) so said file can be opened in a spreadsheet program to further analyze/graph the data. In FIG. 14, an example plot 269 (e.g. sample rate is one second/store rate is one minute) of an example power pack 200 maximum temperature recordings over time is shown, having minute by minute granularity over the entire product warranty period (e.g. five years) can be beneficial in discerning long term host system 600 and power pack 200 temperature trends that without said granularity would not be as valuable.

FIG. 8 illustrates a temperature logging system 230 according to an embodiment. The temperature logging system 230 includes: a microcontroller 238 (e.g. PIC18LF26K22) which is programmed to direct said logging system, a temperature sensor 237 (e.g. MCP9804) communicated with via a bus 213 (e.g. I2C) and connected to the data/back-up power connector 202, non-volatile sample memory 234 including two NOR devices 235, 236 (e.g. M25P16) and communicated with via a SPI (Serial Peripheral Interface) bus, a MicroSD card connector 232 (e.g. Hirose DM3D-SF), a provided MicroSD card 231 which may be installed and uninstalled from the card connector, and an orange LED 233 is lit to indicate MicroSD card activity or a temporary fault condition. In one embodiment, the temperature logging system 230 is programmed for a temperature sample rate of once per second and a temperature store rate of once per minute, although other useful rates may be used. In one embodiment, the temperature sample format is as follows: one byte per sample, the byte format is [MSB] 7 6 5 4 3 2 1 0 [LSB] or in hexadecimal 0xXX, bit 7 is a sign bit where 0x1 represents less than 0 degree Celsius and 0x0 represents greater than or equal to 0 degree Celsius, a sample of 0XFF is not a temperature but an indication of a sample not yet taken. Thus the temperature values can range from −126 to +127 degree Celsius which is within the temperature sensor capability. In one embodiment, a total non-volatile sample memory 234 capacity of 4 MB is used, and if each NOR device is 16 Mbit more than 20+ years of data retention is supported. For example, 4,194,304 samples may be stored which equates to seven plus years of permanently archived temperature samples. The temperature logging system 230 thus supports a sample capacity and a retention period that both exceed a typical 5 year warranty period. Another embodiment may use a larger capacity, e.g. 32 Mbit, NOR device 235-236 (e.g. N25Q032A) to either reduce the present component count from two to one or to replace both NOR devices 235-236. Replacing both would double the sample storage capacity and support a potential 10 year warranty period. The temperature logging system 230 is powered by a dedicated power supply 239 implemented with a low-noise linear regulator (e.g. TL1963A-33) with the charge current connector 201 providing the input source. Using the charge current input 201 as the power supply 239 input advantageously allows the entire temperature logging system 230 to be automatically disabled when host system 600 power is lost and thus does not deplete the supercapacitor voltage while a back-up is in progress.

FIG. 10 illustrates a memory card 300 including one or more storage devices according to an embodiment. One of said storage devices is a NVRAM drive comprised of two solid-state memory types and defined by a “one-to-one” correspondence between the on-board volatile memory 310 and the on-board non-volatile memory 330 capacities. The memory card 300 presents a portion of said capacity as the NVRAM drive's addressable storage capacity. The proportion not counted towards said capacity is determined primarily by the algorithmic type and strength of the ECC (Error Correcting Code) implemented by the FPGA 340 to detect and correct volatile memory data corruption. Host system 600 writes and reads are directed to volatile memory and the smallest unit of transfer is called a sector, typically 512 bytes or 4096 bytes. In one embodiment, the memory card 300 includes sixteen 4 Gb (e.g. Micron MT41K1G4) DDR3L SDRAM components 311-326 and eight 8 Gb (e.g. Samsung K9K8G08U08) SLC NAND components 331-338. The aggregated DRAM component capacity is 8 GiB or 8,589,934,592 bytes as is the aggregated NAND component capacity. There are 15,790,320 sectors addressable from 8 GiB when 32 bytes of ECC is applied to each 512 byte sector. One skilled in the art will understand that other component sizes and capacities may be used. In addition to the DRAM ECC data there can be other limiting factors to the number of addressable sectors on the memory card 300. For example, a backup/restore engine constraint further reduces the addressable sectors from 15,790,320 to 15,790,080. Each K9K8G08U08 component has 512 pages, with a page size of 2,048 bytes, and an additional 64 bytes of “spare” area to store NAND based ECC. The spare area is not counted towards the NAND component's capacity of 1 GiB. NAND fundamentally degrades with every memory card 300 backup/restore cycle, thus a certain proportion of NAND (i.e. capacity) must be “set aside” so as segments of NAND fail they can be remapped to the “set aside” segments. Constraining the memory card 300 addressable sectors to 15,790,080 allows 246,784 NAND pages to be “set aside” from the NAND's aggregated capacity of 8 GiB to compensate for an entire product lifecycle of SLC NAND backup/restore degradation. It is industry practice for storage devices, such as HDD/SSD, to quote storage capacity in “Base 10” and not “Base 2” notation. The 15,790,080 addressable sectors results in an addressable storage capacity of 8,084,520,960 bytes and thus can be marketed (with capacity to spare) as an 8 GB (8,000,000,000 bytes) “base 10” storage device even after the addressable sector reductions for encapsulating the DRAM ECC data. Only the volatile memory 310 contents which can be successfully backed-up to non-volatile memory 320 (i.e. one-to-one) can be presented to the operating system 104 as the memory card 300 addressable storage capacity. The storage capacity presented to the operating system 104 by the device driver 400 must stay constant over the entire memory card 300 product lifecycle. The novel memory card 300 design accounts for the inevitability of NAND degradation over time while simultaneously solving where to store the required DRAM ECC data. The repurposing of otherwise unusable, i.e. unable to be successfully backed-up, DRAM memory to store DRAM ECC data is advantageous as it avoids the need for dedicated ECC DRAM components. Additional benefits of foregoing dedicated ECC DRAM components include: an increased product reliability by reducing points of failure, a decreased power consumption and thus less draw on the supercapacitors while a back-up is in progress, a decreased surface area required to place and route volatile memory components.

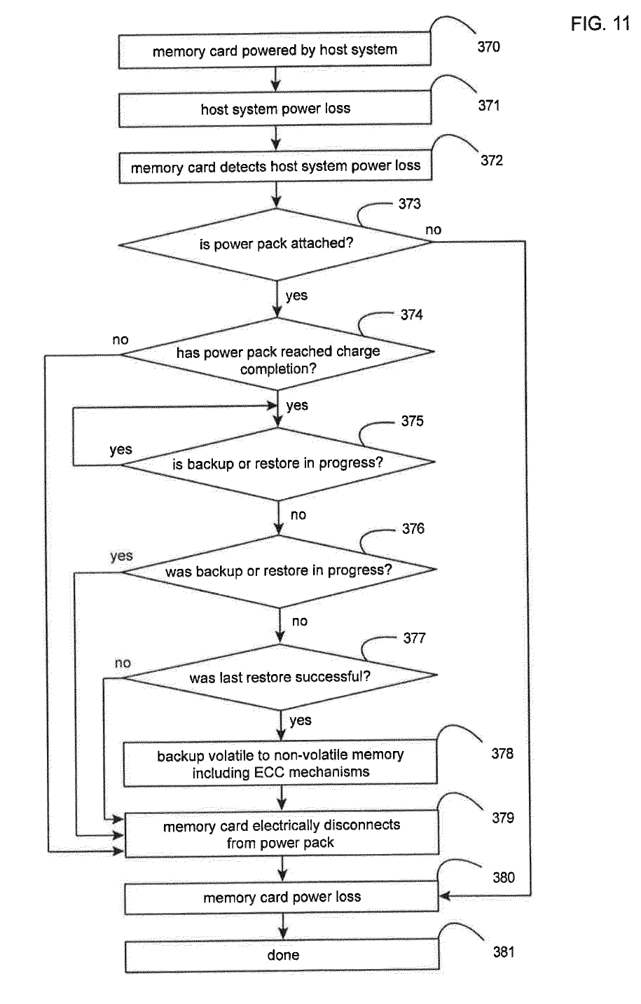

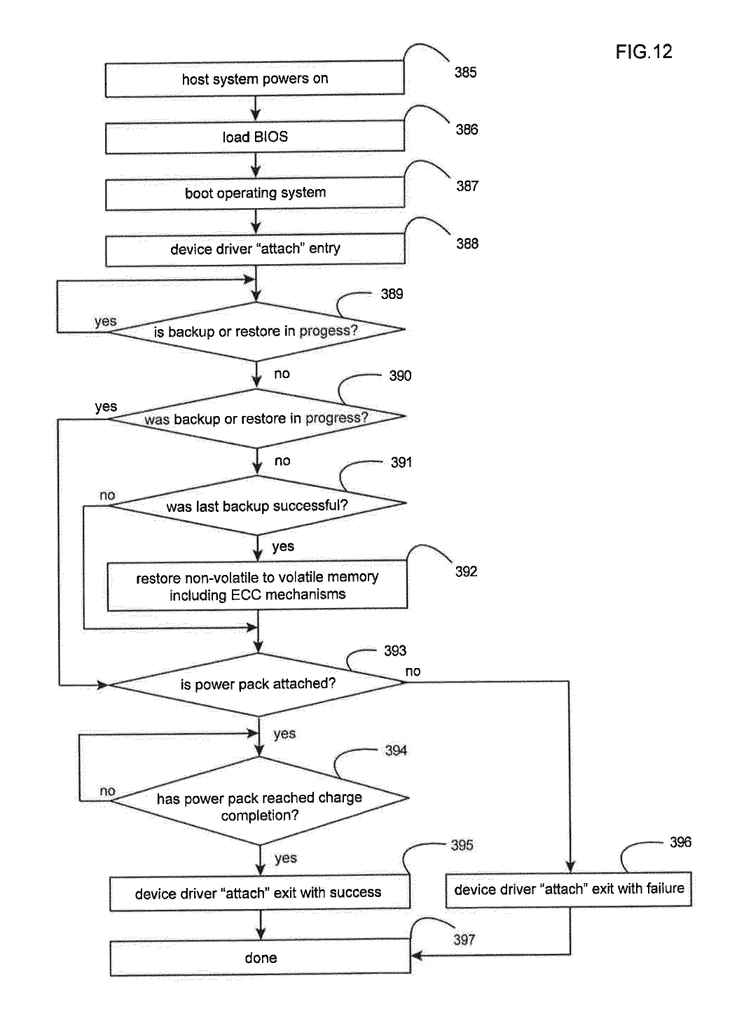

The memory card 300 contains both volatile memory 310 and non-volatile memory 330 and must transfer the contents of the volatile memory 310 to non-volatile memory 330 in the event of a trigger (typically when the memory card 300 host power is lost) in order to guarantee the volatile memory 310 contents are not irrevocably lost and thus requires a power pack 200 which has reached charge completion to power said transfer in its entirety. Charge completion is defined as the amount of charge required to power the transfer of all volatile memory 310 data to non-volatile memory 330. Said trigger event is most commonly a host power failure and/or loss but can be configured to be initiated by any event that has specific device driver 400 support. FIG. 11 illustrates a flowchart of the memory card 300 initiated back-up mechanism according to an embodiment. During normal operating conditions, host related transfers (typically writes and reads) are to and from volatile memory 310 (e.g. DRAM) to maximize performance. Transfers to non-volatile memory 330 (e.g. NAND) only occur upon a defined trigger condition. Then upon a following trigger event (typically the memory card 300 host powering back on) the non-volatile memory 330 (e.g. NAND) is transferred back to the volatile memory 310 (e.g. DRAM) prior to the memory card 300 and device driver 400 allowing storage I/O to and from the host system 600. FIG. 12 illustrates a flowchart of the memory card 300 and device driver 400 controlled restore mechanism according to an embodiment.

FIG. 11 illustrates an embodiment of a back-up process. The process starts with step 370, in which the memory card 300 is powered by the host system 600. In step 371, the host system 600 loses power. In step 372, the memory card 300 detects the host system 600 has lost power. In step 373, the memory card 300 detects if the power pack 200 is attached. If the power pack 200 is attached, then the process proceeds to step 374. If the power pack 200 is not attached then the process proceeds to step 380. In step 374, the memory card 300 determines if the power pack 200 has reached charge completion. If the power pack 200 has reached charge completion then the process proceed to step 375. If the power pack 200 has not reached charge completion then the process proceeds to step 379. In step 375, the memory card 300 determines if a backup process or a restore process is in progress. If neither a backup process nor a restore process is in progress then the process proceeds to step 376. If a backup process or a restore process is in progress then step 375 is repeated. In step 376, the memory card 300 determines if a backup process or a restore process was in progress. If neither a backup process nor a restore process was in progress then the process proceeds to step 377. If a backup process or a restore process was in progress then the process proceeds to step 379. In step 377, the memory card 300 determines if the last restore process was successful. If the last restore process was successful then the process proceeds to step 378. If the last restore process was not successful then the process proceeds to step 379. In step 378, the memory card 300 backs up the volatile memory 310 contents to non-volatile memory 330, including ECC mechanisms, and then the process proceeds to step 379. In step 379, the memory card 300 electrically disconnects itself from the power pack 200 via the back-up power switch 354 and then the process proceeds to step 380. In step 380, the memory card 300 loses power and the process ends 381.

In FIG. 11, in step 379 the memory card 300 is electrically disconnected from the power pack 200. This is accomplished via the back-up power switch circuit 354 located on the memory card 300 and directed by the storage controller 340. The storage controller 340 can be configured to control, i.e. turn on/turn off, a power path controller (e.g. LTC4414) which drives two P-channel MOSFETs (Metal-Oxide-Semiconductor Field-Effect Transistor) (e.g. BSC080P03LS-G) to create a near ideal diode function. The charge completion time of the energy storage unit 240 is a fundamental power pack 200 metric and it's advantageous to reduce said time if possible. The memory card 300 has a minimum working voltage, called the “cutoff voltage”, from which it can operate and below which can be problematic to certain memory card 300 circuitry. For operational correctness, the memory card 300 should not be subjected to a slowly decreasing supply voltage, such as a self discharging power pack 200, that falls below the memory card 300 cutoff voltage. Thus electrically disconnecting 379 the memory card 300 from the power pack 200 at the completion of the back-up process is advantageous as it protects the memory card 300 from crossing the cutoff voltage threshold and removes a drain on the energy storage unit 240. Removing said drain potentially results in an advantageous reduction of the charge completion time on the next energy storage unit 240 charging cycle. The power switch circuit 354 also enables the memory card 300 to efficiently switch between the host system 600 provided power, via the PCIe edge connector 301, and the back-up power provided by the power pack 200. Alternate embodiments may use Schottky diode OR'ing, but this alternative imparts a relatively large voltage drop of approximately 400 mV, with the actual drop being dependent on the current magnitude. The power switch circuit 354 provides an approximate 20× reduction in said drop to a nominal 20 mV, thus advantageously enabling a larger proportion of the supercapacitor voltage to be utilized for the back-up process while simultaneously decreasing memory card 300 power dissipation.

FIG. 12 illustrates an embodiment of a solid-state storage system 100 restore process. The process starts with step 385, in which the host system 600 is powered on. In step 386, the BIOS (Basic Input/Output System) is loaded. In step 387, the operating system 104 is booted. In step 388, the device driver 400 “attach” subroutine is entered. In step 389, the device driver 400 determines if a backup process or a restore process is in progress. If neither a backup process nor a restore process is in progress then the process proceeds to step 390. If a backup process or a restore process is in progress then step 389 is repeated. In step 390, the device driver 400 determines if a backup process or a restore process was in progress. If neither a backup process nor a restore process was in progress then the process proceeds to step 391. If a backup process or a restore process was in progress then the process proceeds to step 393. In step 391, the device driver 400 determines if the last backup process was successful. If the last backup process was successful then the process proceeds to step 392. If the last backup process was not successful then the process proceeds to step 393. In step 392, the device driver 400 restores the volatile memory 310 contents from the non-volatile memory 330, including ECC mechanisms, and then the process proceeds to step 393. In step 393, the device driver 400 detects if the power pack 200 is attached. If the power pack 200 is attached, then the process proceeds to step 394. If the power pack 200 is not attached then the process proceeds to step 396. In step 394, the device driver 400 determines if the power pack 200 has reached charge completion. If the power pack 200 has reached charge completion then proceed to step 395. If the power pack 200 has not reached charge completion then step 394 is repeated. In step 395, the device driver 400 “attach” subroutine is exited with success and the process ends 397. In step 396, the device driver 400 “attach” subroutine is exited with failure and the process ends 397.

The energy storage unit 240 charge procedure must be completed prior to the memory card 300 accepting data by the operating system 104 to guarantee memory card 300 data integrity, as any data transferred is at risk of loss if the host system 600 loses power prior to power pack 200 charge completion. Charge completion is the amount of charge required to power the transfer of all volatile memory 310 data to non-volatile memory 330. The power pack 200 can be combined with an equally adept device driver 400 to avoid any possibility of memory card 300 data loss resulting from a host 600 power failure, including back-to-back host 600 power losses. In certain aspects, the device driver 400 is written to disallow any data transfer to the memory card 300 if the power pack 200 has not attained charge completion or is unconnected. A best case charge completion time referred to as “no wait” is defined as less than the combined duration to reboot the host 600 after a power loss and to perform the required restore process of the non-volatile memory 330 contents transferring to volatile memory 310. A “no wait” charge time is one which can be completely hidden or overlapped by the time required by other unrelated procedures operating in parallel. This is preferable to having either the device driver 400 wait for the charge process to complete or not wait and risk data loss. The worst case is a memory card 300 whose device driver 400 is not aware of the time required to reach charge completion and must either have a charge completion time less than every possible host reboot and restore duration, or be susceptible to data loss until charge completion is reached. A device driver 400 written as so described in FIG. 12 can determine the charge completion status via direct communication with the memory card 300 and other fault conditions indirectly via the power pack 200. The indirect communication is accomplished via the data/back-up power cable which connects the memory card connector 302 to the power pack connector 202. Once the device driver 400 has determined both the charge completion status and any relevant fault status it can then act accordingly to avoid possible data loss. The device driver 400 does so by waiting for charge completion to complete 394 prior to the device driver 400 exiting the operating system 104 “attach” subroutine with success. Host system 600 writes to the memory card 300 cannot occur prior to the drive driver 400 successfully “attaching”. Thus the device driver 400 has closed any opportunity for data loss as no data writes occur prior to charge completion 394, and any data writes after charge completion 394 can survive a host 600 power failure per definition (of charge completion).

In FIG. 10, the memory card 300 includes: an FPGA 340 which implements the storage controller, volatile memory 310 components (e.g. DRAM) directly soldered to the memory card 300 or industry standard DIMMs, and non-volatile memory 330 components (e.g. NAND) directly soldered to the memory card 300 or a daughter card which is then attached to the memory card 300.

The memory card 300 facilitates the monitoring of the on-board power pack 200 voltage by way of an A/D voltage convertor 353 (e.g. TLV3011) via an I2C bus connection to the FPGA 340. A temperature sensor 359 (e.g. MCP9804) communicates with the FPGA 340 via an I2C bus. In addition to the PCIe edge connector 301 there are SATA connectors 346-347 that connect to the FPGA transceivers and are used by either HA links 355-356 or for SSD attachment 357-358. The data/back-up power 302 connector (e.g. Molex SDA-70555 header) is an input which couples via a cable to an output comprised of the power pack 200 data/back-up power connector 202 (e.g. Molex SDA-70555 header). Both the PCIe edge connector 301 and the data/back-up power connector 302 are both protected by TVS devices 339, 341, these provide a level of protection against end-user initiated ESD events and host power supply unit 630 voltage surge events. The MicroSD card connector 348 enables the PCI card to load a new FPGA 340 bitstream without requiring the card to be installed in a host system 600. The external drive activity connector 349 allows drive activity (i.e. storage I/O) to be displayed from a suitable host system 600 LED The buzzer 350 can be configured to provide audible feedback when a back-up in progress, in which case the sound a delivery truck makes when “backing-up” is played. Four on-board LEDs are used to indicate the following conditions: a green LED 342 is lit when the PCIe edge connector 12V supply is present, a yellow LED 343 is lit to indicate a restore is in progress, a red LED 344 is lit to indicate a back-up is in progress, and a blue LED 345 is lit to indicate drive activity (i.e. storage I/O). Two PCB holes 351-352 are for mounting a custom PCIe bracket.

A device driver 400 specifically written for the memory card 300 is required for an operating system 104 (e.g. Solaris, FreeBSD, VMware, Linux, Windows) to recognize and successfully “attach” the memory card 300 as a storage device. A custom device driver 400 enables an expanded scope for the interrupt processing mechanism. Interrupts are commonly used to implement high performance I/O handling such as reads and writes to a storage device. The embodiments shown in FIG. 6 and FIG. 10 also use interrupts to provide high performance intercommunication between the memory card 300, power pack 200, and the device driver 400. The interrupt mechanism used is in contrast to the otherwise used and less performant polling mechanism. The use of interrupts enables high speed communication of critical events between the memory card 300, power pack 200, and the device driver 400. Being aware of said events allows the device driver 400 to ascertain additional details and then intelligently act upon said information. Examples of such are: power pack 200 attaining charge completion, power pack 200 losing charge completion, memory card 300 to power pack 200 cable fault, power pack 200 to charge current source 642 cable fault, NVRAM read ECC one bit correction, memory card 300 temperature limit exceeded, power pack 200 temperature limit exceeded, power pack 200 supercap voltage limit exceeded, HA link connected to memory card 300, HA link disconnected from memory card 300, SSD connected to memory card 300, SSD disconnected from memory card 300.

An HBA is unlike a memory card 300 operating as a NVRAM storage device, in that most HBAs can disable on-board volatile memory, referred to as an HBA “cache”, if the associated battery back-up is non-functional and will continue to operate correctly although without the performance enhancing aspects of said cache. This operational correctness irrespective of BBU (Battery Backup Unit) status is common to most HBAs. The NVRAM function of the memory card 300 is not operationally correct without the power pack 200 being attached and having reached charge completion. An HBA can disable its cache in case of a BBU fault and continue writing data to one or more attached storage devices as the HBA cache is not typically a storage device recognized by the operating system 104. Typically an HBA is not presented to the operating system 104 as a storage device unless storage devices (e.g. HDD/SSD) are attached, this holds irrespective of whether the HBA includes an on-board cache. Contrary to an HBA, the memory card 300 is typically presented to the operating system 104 as a NVRAM storage device irrespective of whether storage devices (e.g. SATA) are attached.

So the volatile memory 310 of the memory card 300 is presented to the operating system 104 as a storage device via the device driver 400. Specifically said storage device is a block storage device. Block storage devices are accessed by the operating system 104 kernel as a set of randomly addressable logical blocks and thus can support a file system 103. Typically, operating systems 104 only allow block devices to support a file system 103. For example, typically a character device cannot be treated as a block storage device and thus cannot support a file system. Thus typically, an HBA with on-board cache and a functioning BBU but without any storage devices attached will not present, via the HBA device driver, the cache as a storage device, block or otherwise, to the operating system 104.

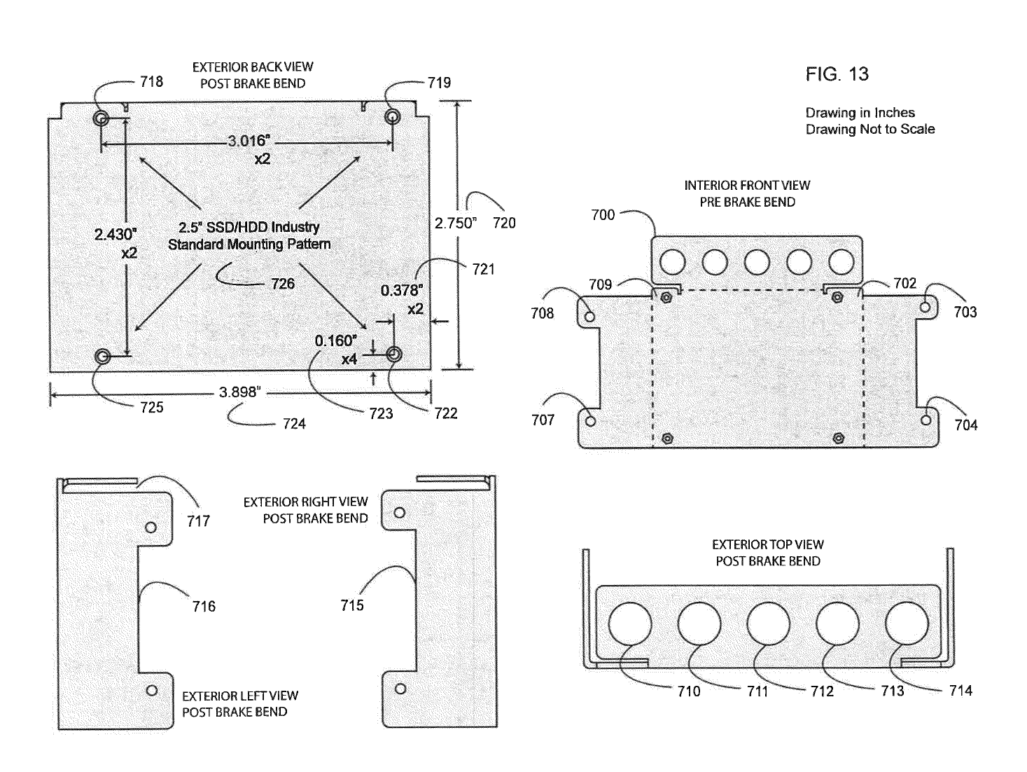

FIG. 13 illustrates features of a power pack shell according to an embodiment. The shell 700 is integral to the power pack 200 as it surrounds and protects the control module 210 and the supercap subsystem 240 (e.g. supercapacitors) from damage during handling and installation. The shell 700 includes unique form factor features: a 2.5″ HDD/SSD industry standard mounting pattern 721, 723, 726, a 2.5″ HDD/SSD industry standard mounting thread and nut 718, 719, 722, 725, the shell 700 length 724 and width 720 are constrained to within the 2.5″ HDD/SSD industry standard length and width, a venting window 710-714 per supercapacitor, a space for supercapacitor expansion 717, air flow cutouts to maximize shell cooling 715-716, mounting holes 703, 704, 707, 708 for attachment to the control module 210 PCB, and two cutouts 702, 709 to facilitate successful self-clinching nut installation. Enabling the power pack 200 to be mounted using the 2.5″ SSD/HDD industry standard is advantageous to the successful fitment of the power pack 200 into the host system 600.

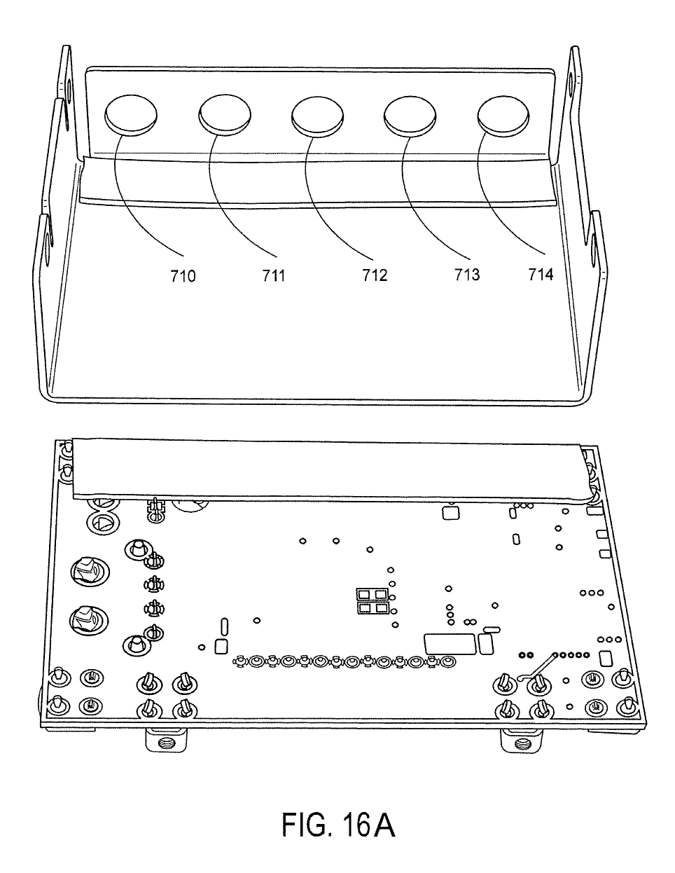

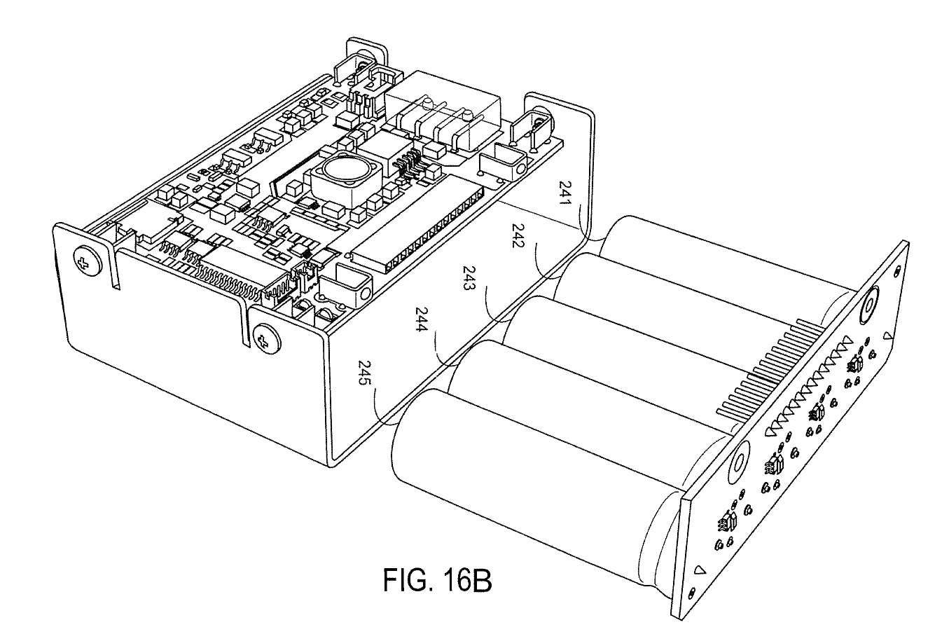

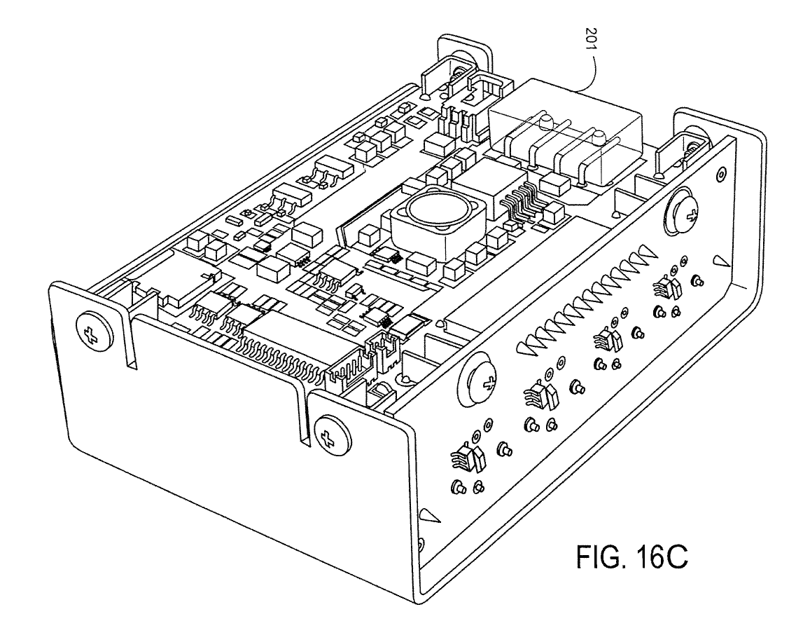

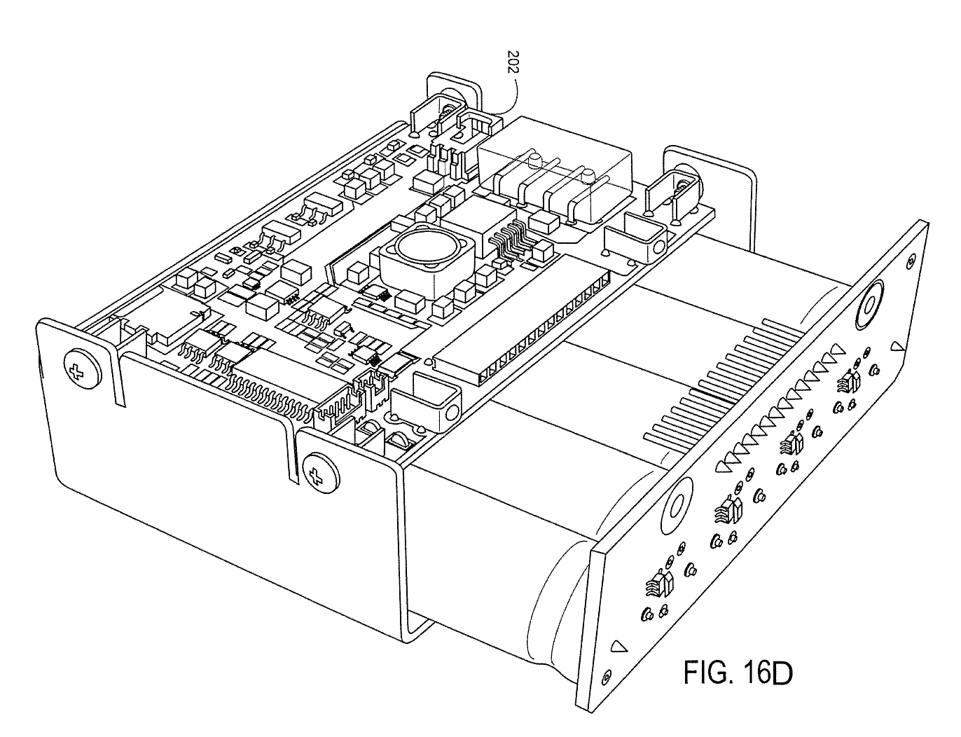

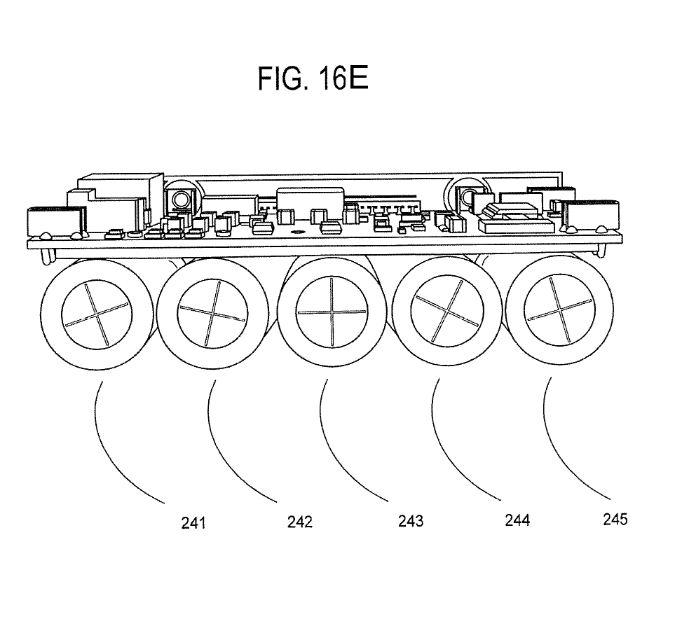

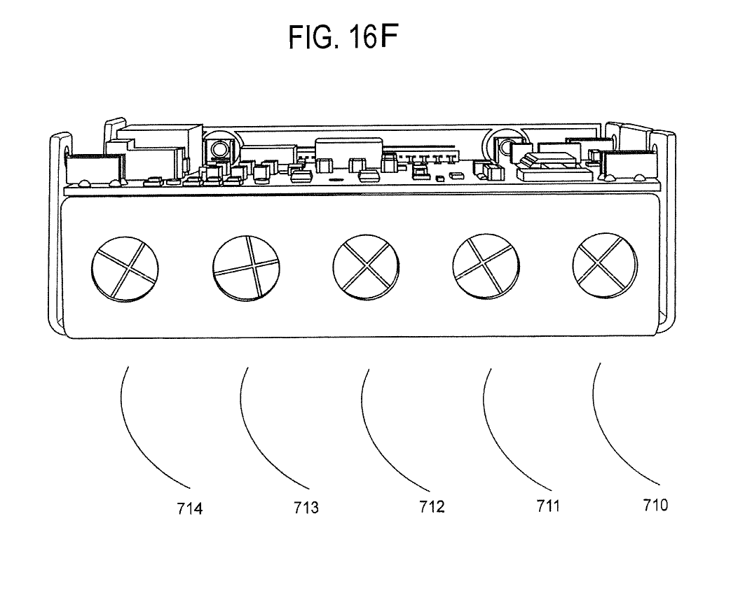

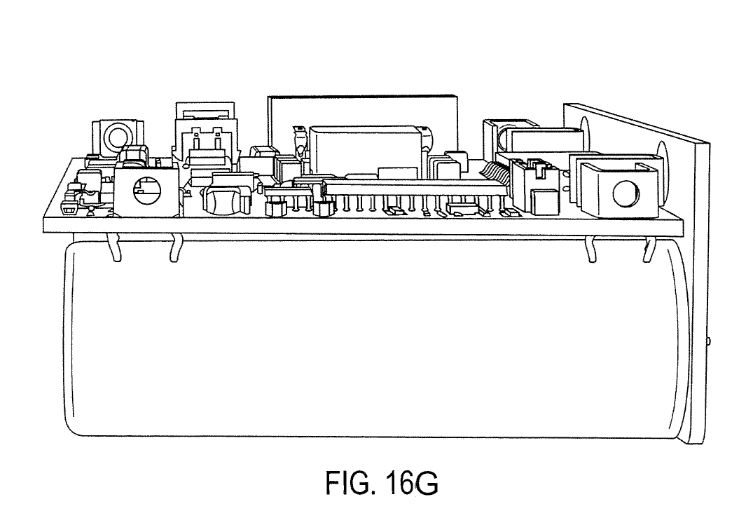

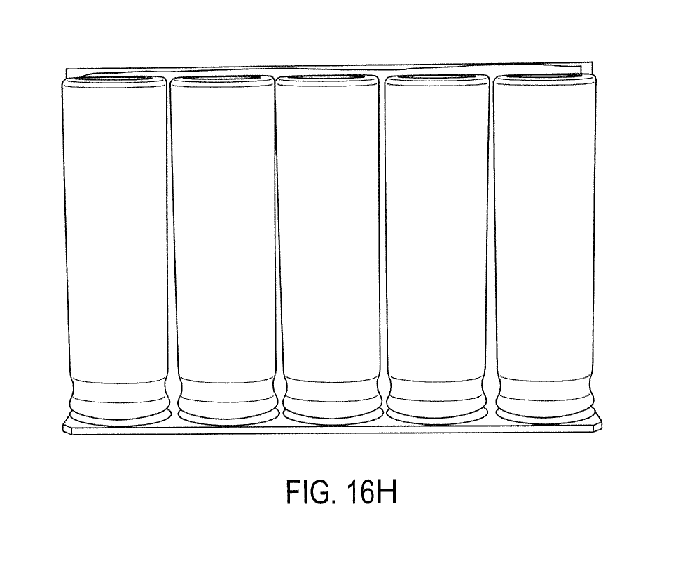

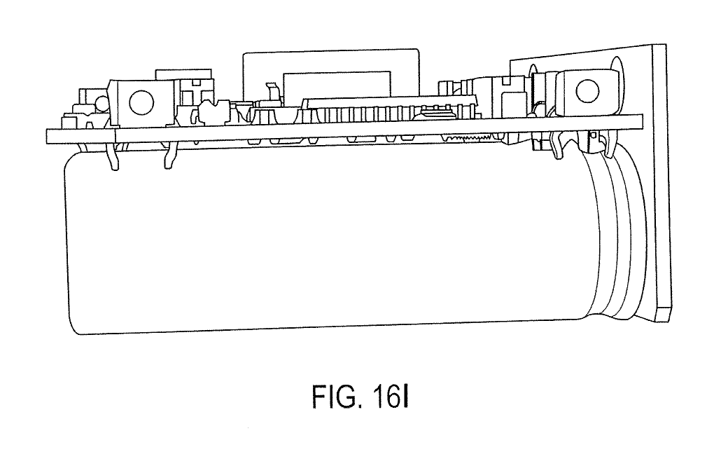

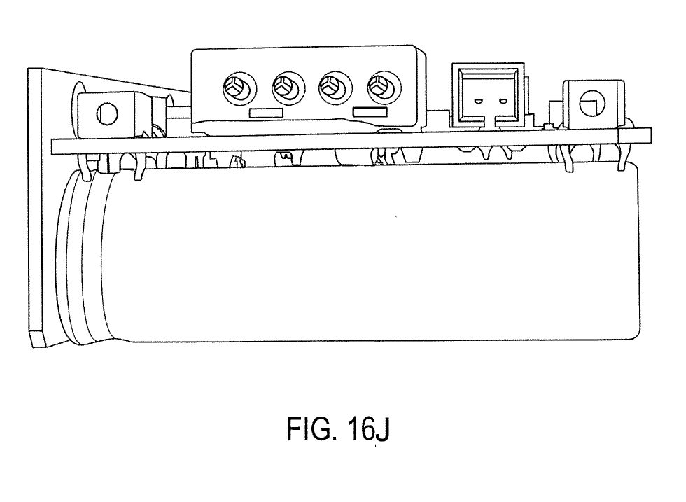

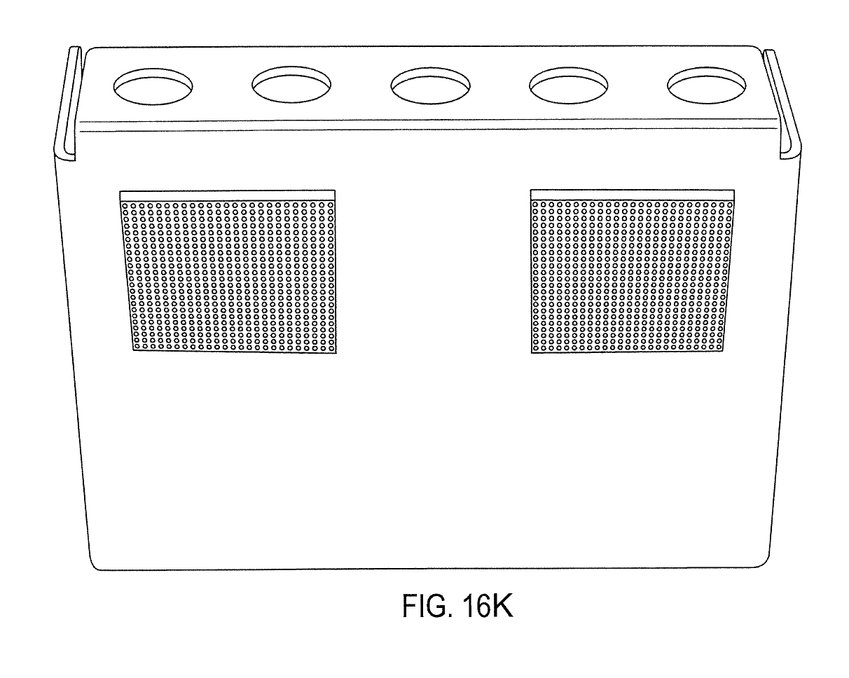

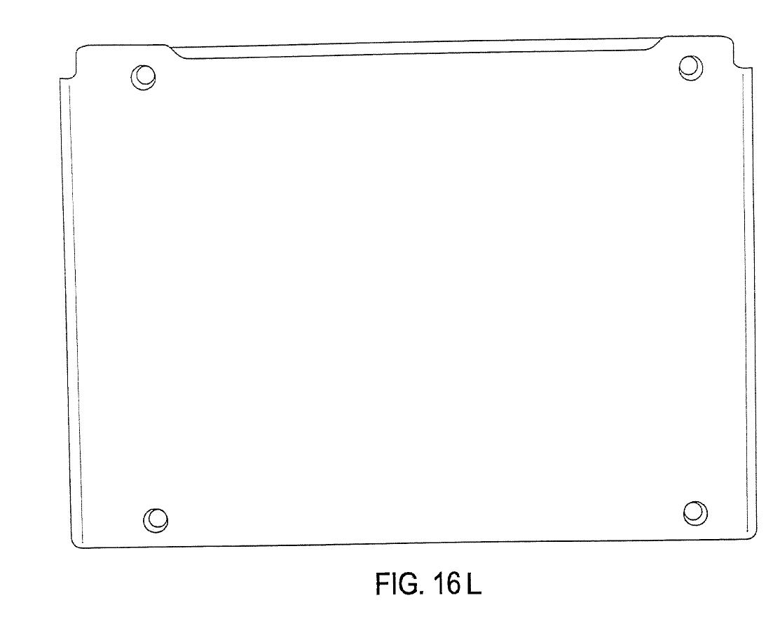

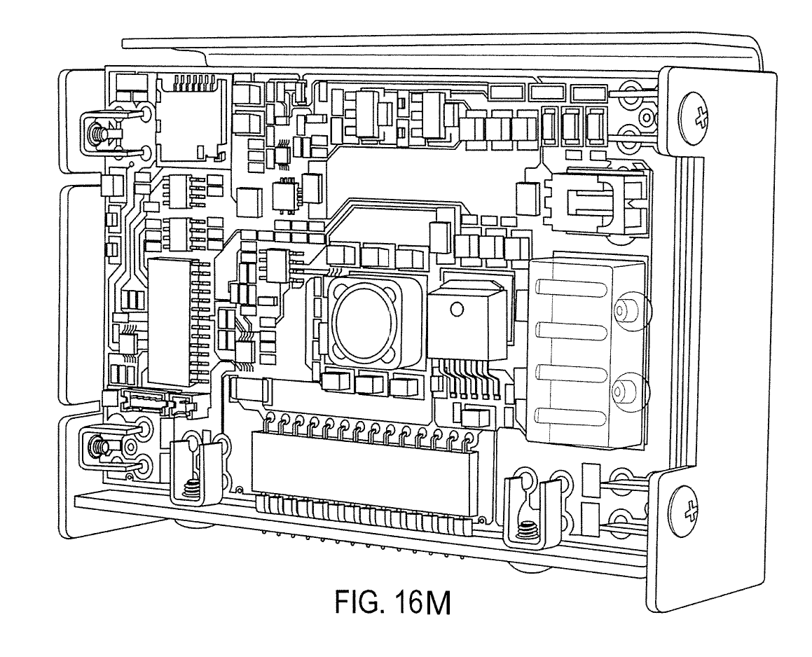

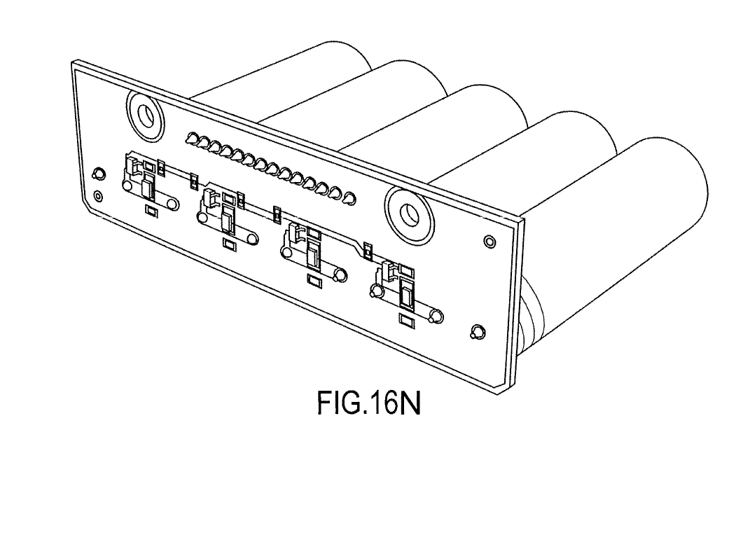

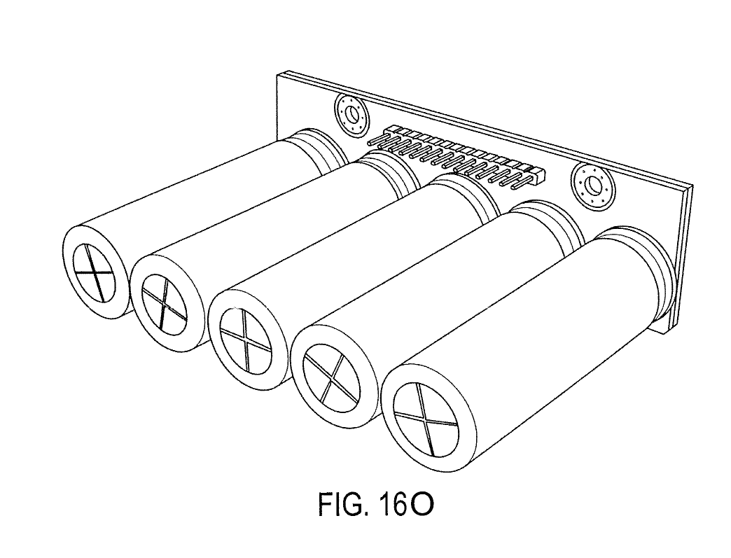

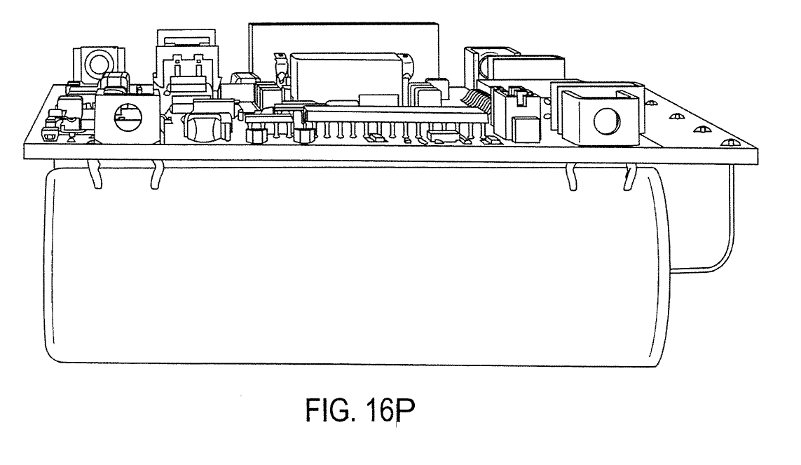

The shell 700 is integral to the power pack design and protects the supercapacitors from damage during handling while still enabling visual inspection of the supercapacitor's physical state (e.g. vented). As seen in FIG. 16A and FIG. 16F, for example, the aluminum shell includes a small circular window (e.g. 400 mils in diameter; windows 710-714) for each supercapacitor allowing the end-user to view the vent (typically implemented as a plus sign engraved in the metal cap). If a supercapacitor would “vent” the damage would be visible without disassembly of the power pack. Venting is defined as a process which originates internal to the supercapacitor and results in gas generation which forces the metal cap to be breached. Supercapacitors can also expand as they age, thus the window advantageously allows the end-user to visibly discern said expansion and again without disassembly of the power pack. The shell can be formed in various manners, including by laser cutting from an aluminum plate (typically 62 mils) and can inexpensively be formed into the resulting box using a “Pan & Box Brake” device.

The primary PCB, henceforth the “control module”, contains a majority of the power pack electronics, including a dual stage charging circuit, a load switch with supporting discrete components, all external cable connectors, and a microprocessor controlled temperature logging subsystem with an industry standard MicroSD card interface. The secondary PCB, henceforth the “supercap subsystem”, includes the supercapacitors and the proportionally inexpensive active balancing components.

By requiring only the supercap subsystem to be replaced when the supercapacitors have reached end-of-life, and not the control module or the aluminum shell, substantial cost saving can be achieved compared to replacing the entire power pack.

A minimized power pack form factor is advantageous as it improves host chassis compatibility and maximizes possible mounting locations inside said chassis. The attachment of the control module PCB perpendicular to the supercap subsystem PCB is the basis for the power pack's unique mechanical and form factor attributes. Firstly, substantially perpendicular PCBs inherently place the supercapacitor's body in substantially parallel orientation with the back side of the control module PCB (See FIG. 16). The distance between the supercapacitor's body and control module PCB is further minimized with strategic placement of the through hole components on the top side of the control module to allow these leads to utilize the gaps between the supercapacitor's cylindrical bodies. Lead trimming on the control module's back side is used for all other through hole components whose leads would otherwise impede a close proximity between the supercapacitor body and the back side of the control module PCB. This provides an inherent “folding” effect without requiring the supercapacitor leads to be bent and allows the supercapacitor's rubber bung to be in direct contact with the supercap subsystem's PCB thus advantageously allowing the supercapacitor's leads to be kept both straight and of reduced length. Secondly, the exceedingly short supercapacitor lead length resulting from the substantially perpendicular PCB design results in a very compact power pack length. Said length is equal to just the supercapacitor body length plus the supercap subsystem PCB thickness (typically 62 mils) plus a small solder fillet on the back side. In certain aspects, the control module PCB overhangs the supercapacitor vent to allow an expected body elongation as the supercapacitor ages.

There are two attachment mechanisms used to combine the two perpendicular PCBs: first being the electrical connection which uses an industry standard vertical through hole header on the supercap subsystem PCB and a matching right angle through hole receiver on the control module PCB; and second are two screw terminals, one on each side of the header/receiver pair, which provides the structural integrity between the two PCBs and provides a built-in locking mechanism for the header/receiver pair. In certain aspects, the screw terminals are advantageously located on the control module PCB with no matching connector per se (just a drilled hole) on the supercap subsystem PCB. Thus minimizing components and cost (even the screws can be reused) of the replacement supercap subsystem.

In certain aspects, by using two strips of foam (typically 62 mils thick), the supercapacitors can be secured at their venting end, thus disallowing movement towards either the control module PCB or the opposing aluminum shield. Movement in the other direction is inherently restricted by the soldered lead orientation. This is important as during product shipping or installation, handling can create the forces necessary to move the supercapacitor body which can negatively affect the supercapacitors' longevity. The first foam strip is placed beneath the supercap subsystem PCB and the second strip is similarly placed on the aluminum shield.

Mounting of the power pack can be accomplished using a custom fixture specific to a certain host chassis and sharing the screw terminals which are used to secure the aluminum shell or by attaching re-closable fasteners (typically 3M Dual Lock SJ4570) on the flat surface of the aluminum shell back.

For sake of comparison, define the “folding effect” as placing a supercapacitor's cylindrical body in parallel to the back side of control module PCB. An inferior approach to obtaining the “folding effect” is to bend the supercapacitor leads 90 degrees and solder the supercapacitors directly onto the back side of the control module PCB itself. This “bend and solder” approach also increases the power pack's overall length and a extended PCB is required for the leads to be bent 90 degrees compared to just the PCB thickness detailed above. As a bent lead requires a shape more similar to an arc than a true 90 degree bend to prevent damage to the leads immediate entry into the supercapacitor. The “bend and solder” approach would in addition to increasing the power pack form factor also forgo it's ease of replacement. Notably the “bend and solder” approach requires highly technical soldering expertise and tools. Practicality would dictate the entire power pack be returned to the manufacturer to perform the “bend and solder” approach, thus foregoing the benefits of an “in the field” replacement procedure performed directly by the end-user.

As shown in FIG. 16B and FIG. 16D, for example, the supercapacitor subsystem can be replaced by removing just two phillips-head screws and sliding out the supercap subsystem like one would with a “dresser drawer”. The control module is affixed to the aluminum shell and neither requires adjustment or removal during replacement of the supercap subsystem. When inserting the supercap subsystem the high pin count header/receiver combination provides a precise amount of insertion force and automatic alignment. The aluminum shell is shaped to not allow misalignment of the header as it slides into the receiver. Following supercap subsystem insertion reinstall the two screws are tightened to complete the replacement procedure. As shown in this embodiment, an industry standard 14 pin 0.100″ header/receiver pair has been used which advantageously provides both high reliability and volume (i.e. low cost) availability. It should be appreciated that other header/receiver connections may be used. Too many electronic products today are specifically designed to require disposal once the energy source has reached end-of-life, and the power pack presented here is a step in the right direction as far as environmental sensibility.

According to an embodiment, a back-up power unit is provided for use with a PCI based solid-state storage device, the back-up power unit typically includes a first printed circuit board (PCB) comprising power control electronics and a first electrical interface, a second PCB comprising a second electrical interface configured to removably mate with the first electrical interface of the first PCB, and a plurality of supercapacitors connected to the second PCB such that a length of the supercapacitors extends substantially perpendicular to a plane defined by the second PCB. When the second electrical interface of the second PCB is mated with first electrical interface of the first PCB, the length of the plurality of supercapacitors extends substantially parallel to a plane defined by the first PCB, and whereby the plurality of supercapacitors provide power to the power control electronics through the mated first and second electrical connectors. In certain aspects, the back-up power unit further includes a housing structure that holds the first PCB and which is configured to receive and enclose the plurality of supercapacitors when the first electrical interface is mated with the second electrical interface. In certain aspects, the housing structure comprises a unitary folded sheet of aluminum. In certain aspects, the first and second electrical connectors comprise a header/receiver pair. In certain aspects, the header/receiver pair comprises a 14 pin header/receiver pair. In certain aspects, the housing structure includes a plurality of openings positioned proximal to where an end of each of the plurality of supercapacitors would be when the second electrical interface of the second PCB is mated with first electrical interface of the first PCB. In certain aspects, the first PCB includes a power cable interface adapted to receive a power cable connected to a PCI based solid-state storage device. In certain aspects, the power control electronics include a dual stage constant current/constant voltage charging circuit and a load switch that controls power provided to the power cable from the plurality of supercapacitors. In certain aspects, the first PCB includes a two-way data cable interface adapted to receive a data cable connected to a PCI based solid-state storage device and to send and receive data signals over a connected data cable. In certain aspects, the plurality of supercapacitors are connected in series and the second PCB includes an active balancing circuit adapted to regulate the voltage on each supercapacitor.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the disclosed subject matter (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or example language (e.g., “such as”) provided herein, is intended merely to better illuminate the disclosed subject matter and does not pose a limitation on the scope of the invention unless otherwise claimed. No language in the specification should be construed as indicating any non-claimed element as essential to the practice of the invention.

Variations of the embodiments disclosed herein may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A back-up power pack comprising:
an energy storage unit;
a first connection, wherein a charge source is attachable to the first connection, the charge source providing a charge current to the first connection, the charge current circumventing a data storage device;
a charging circuit, wherein the first connection provides the charge current to the charging circuit, and the charging circuit charges the energy storage unit; and
a second connection, wherein the data storage device is attachable to the second connection, the energy storage unit providing a back-up power to the second connection, the second connection providing the back-up power to the data storage device.

2. The back-up power pack of claim 1, wherein the first connection comprises a first power connector, and the charge source couples to the first power connector via a power cable.

3. The back-up power pack of claim 1, wherein the charge source comprises one of the following: a power supply unit connection, a motherboard connection, a motherboard riser connection, and a PCIe charge supply card connection.

4. The back-up power pack of claim 3, wherein the first connection comprises a first power connector.

5. The back-up power pack of claim 4, wherein the power supply unit connection comprises one of the following: a power supply cable and a power unit connector, wherein the power supply cable is coupled to the first power connector via an adapter cable, wherein the power unit connector and the first power connector are coupled by a power unit cable.

6. The back-up power pack of claim 4, wherein the motherboard connection is comprised of a motherboard power connector, wherein the motherboard power connector and the first power connector are coupled by a motherboard power cable.

7. The back-up power pack of claim 4, wherein the motherboard riser connection is comprised of a riser power connector, wherein the riser power connector and the first power connector are coupled by a riser power cable.

8. The back-up power pack of claim 4, wherein the PCIe charge supply card connection is comprised of a supply card power connector, wherein the supply card power connector and the first power connector are coupled by a supply card power cable.

9. The back-up power pack of claim 1, further comprising a load switch, wherein the energy storage unit provides the back-up power to the load switch, the back-up power is coupled to the second connection when the load switch is in a first switch state and the back-up power is uncoupled from the second connection when the load switch is in a second switch state.

10. The back-up power pack of claim 9, further comprising a memory element, wherein the memory element transitions to a first element state when an energy storage voltage reaches a first predefined voltage and the memory element transitions to a second element state when the energy storage voltage reaches a second predefined voltage, wherein the load switch transitions to the first switch state when the memory element transitions to the first element state and the load switch transitions to the second switch state when the memory element transitions to the second element state.

11. The back-up power pack of claim 1, wherein the second connection comprises a second power connector.

12. The back-up power pack of claim 1, wherein the data storage device comprises a volatile memory and a non-volatile memory, wherein the back-up power enables a transfer of the volatile memory contents to the non-volatile memory.

13. The back-up power pack of claim 12, wherein the volatile memory is accessed via a device driver by an operating system as a block device, wherein the block device supports a file system, wherein an operating system kernel accesses the block device as a set of randomly addressable logical blocks.

14. The back-up power pack of claim 1, wherein the charging circuit comprises a constant current charger and a constant voltage charger.

15. The back-up power pack of claim 1, wherein the energy storage unit is replaceable by an end-user.

16. The back-up power pack of claim 1, wherein the energy storage unit comprises a supercapacitor.

17. The back-up power pack of claim 16, wherein the energy storage unit comprises the supercapacitor and an active balance circuit.

18. The back-up power pack of claim 1, further comprising a temperature logging system, wherein a temperature is sampled at a sample rate and a temperature value is stored to a non-volatile sample memory at a store rate, wherein the temperature value is a highest temperature value in a set of temperature values sampled since a last temperature value was stored.

19. The back-up power pack of claim 18, wherein the non-volatile sample memory has a capacity to store a back-up power pack warranty period worth of samples at the sample rate and a retention period of the non-volatile sample memory exceeds the warranty period.

20. The back-up power pack of claim 19, wherein the sample rate is once per second and the store rate is once per minute and the warranty period is five years.
